(19) United States
(12) Patent Application Publication
(10) Pub. No.: US 2025/0052810 A1
(43) Pub. Date: Feb. 13, 2025

(54) METHOD FOR ASSESSING CONDITION OF AN IRRADIATED ELECTRONIC DEVICE

(71) Applicant: Nokomis, Inc., Canonsburg, PA (US)

(72) Inventors: Walter J. Keller, III, Bridgeville, PA (US); Kenneth H. Munson, JR., Murrysville, PA (US); Anastazia Polakovsky, Tarrs, PA (US)

(73) Assignee: Nokomis, Inc., Canonsburg, PA (US)

(21) Appl. No.: 18/732,528

(22) Filed: Jun. 3, 2024

Related U.S. Application Data
(60) Provisional application No. 63/531,361, filed on Aug. 8, 2023.

(51) Int. Cl. G01R 31/311

(52) U.S. Cl. CPC G01R 31/311

(57) ABSTRACT

A method includes the steps of energizing, in a test fixture with a combination of a power signal and a clock signal, an electrical device selected from a plurality of electrical devices, measuring a first value of a parameter of the electrical device in a first emission of an electromagnetic energy in a radio frequency (RF) spectrum emitted from energized electrical device, irradiating the electrical device, irradiating the electrical device with a radiation dose in a radiation type, measuring a second value of the parameter in the second emission of the electromagnetic energy in the RF spectrum emitted from the energized and irradiated electrical device, measuring a difference between the first value and the second value, and determining a condition of the electrical device based on a measured difference.

### CROSS-REFERENCE TO RELATED APPLICATIONS

This nonprovisional application claims the benefit of priority, under 35 U.S.C. .sctn. 119(e), to a pending U.S. Provisional Patent Application Ser. No. 63/531,361 filed on Aug. 8, 2023 and titled “METHOD FOR ASSESSING CONDITION OF A STRESSED ELECTRONIC DEVICE”, which is hereby incorporated by reference in its entirety.

This document incorporates by reference the disclosures and/or teachings of the following documents in their entirety: U.S. Pat. No. 7,515,094 entitled “Advanced Electromagnetic Location of Electronic Equipment”, U.S. Pat. No. 8,063,813 entitled “Active Improvised Explosive Device (IED) Electronic Signature Detection”, U.S. Pat. No. 8,537,050 entitled “Identification and Analysis of source Emissions Through Harmonic Phase Comparison”, U.S. Pat. No. 8,643,539 entitled “Advance Manufacturing Monitoring and Diagnostic Tool”, U.S. Pat. No. 9,059,189 entitled “Integrated Circuit with Electromagnetic Energy Anomaly Detection and Processing”, U.S. Pat. No. 9,642,014 entitled “Active Detection of Part Anomalies for Physical Cyber Security”, U.S. Pat. No. 9,772,363 entitled “Automated Analysis of RF Effects on Electronic Devices through the use of device unintended emissions”, U.S. Pat. No. 9,851,386 entitled “Method and Apparatus for Detection and Identification of Counterfeit and Substandard Electronics”, U.S. Pat. No. 10,235,523 entitled “Avionics Protection Apparatus and Method”, U.S. Pat. No. 10,395,032 entitled “Detection of malicious software, firmware, ip cores and circuitry via unintended emissions”, U.S. Pat. No. 10,475,754 entitled “System and Method for Physically Detecting Counterfeit Electronics”, U.S. Pat. No. 11,029,347 entitled “ELECTRONICS EQUIPMENT TESTING APPARATUS AND METHOD UTILIZING UNINTENDED RF EMISSION FEATURES”, U.S. Pat. No. 11,069,952 entitled ELECTRONICS INSITU TESTING APPARATUS AND METHOD UTILIZING UNINTENDED RF EMISSIONS FEATURES”, U.S. Pat. No. 11,879,935 entitled “TESTING OF MICROELECTRONICS DEVICE AND METHOD”.

### STATEMENT REGARDING FEDERALLY SPONSORED RESEARCH AND DEVELOPMENT

N/A

### REFERENCE TO SEQUENCE LISTING, A TABLE, OR A COMPUTER PROGRAM LISTING COMPACT DISC APPENDIX

N/A

### TECHNICAL FIELD

The subject matter relates to electronic devices. The subject matter may relate to assessing a condition of an electronic device exposed to atomic Irradiations. The subject matter may relate to assessing the survivability of electronic devices that are subjected to radiation. The subject matter may relate to a method of using emissions of electromagnetic energy in a radio frequency (RF) range to assess a condition of the electronic devices that are subjected to radiation. The subject matter may relate to a method of using emissions of electromagnetic energy in a radio frequency (RF) range to assess a condition of the electronic devices that are subjected to accelerated Irradiations. The subject matter may relate to a method of using RF emissions to access a degradation of an irradiated electrical device.

### BRIEF DESCRIPTION OF THE DRAWINGS

The accompanying drawings are incorporated in and constitute part of the specification and illustrate various embodiments. In the drawings:

FIG. 1 illustrates exemplary parameters in the emission signature waveform;

FIG. 2 illustrates an exemplary fixture that may be designed to test electronic devices;

FIG. 3 illustrates a perspective view of an exemplary enclosure and a device combining a receiver with a signal processing unit;

FIG. 4 illustrates an elevation view of an exemplary irradiation unit;

FIG. 5 illustrates a block diagram of an exemplary receiver;

FIG. 6 illustrates a block diagram of an exemplary signal processing unit;

FIG. 7 illustrates an exemplary representation of non-linear products;

FIG. 8 illustrates a block diagram of an exemplary electrical device;

FIG. 9 illustrates an exemplary clock input applied to the electrical device of FIG. 8;

FIG. 10 illustrates an expected designed functional output signal from the electrical device of FIG. 8;

FIG. 11 illustrates an unintended toggling of a functional output as observed in the time domain after irradiation of the electrical device of FIG. 8;

FIG. 12 illustrates a portion of an exemplary baseline emission signature and a portion of the emission signature of the electrical device of FIG. 8 after irradiation;

FIG. 13 illustrates a portion of an exemplary baseline emission signature and a portion of the emission signature of the electrical device of FIG. 8 after irradiation;

FIG. 14 illustrates an unintended toggling of the functional output of the electrical device of FIG. 8;

FIG. 15 illustrates an enlarged widened envelop of a 2.5 MHz harmonic after 30 krad radiation;

FIG. 16 illustrates an enlarged different envelop of a 1.667 MHz harmonic after 30 krad radiation;

FIG. 17 illustrates a broadband view of an output signature transition;

FIG. 18 illustrates a broadband view of an output signature transition;

FIG. 19 illustrates exemplary effects on the electrical device of FIG. 8 due to beta radiation;

FIG. 20 illustrates effects on the electrical device of FIG. 8 due to gamma radiation;

FIG. 21 illustrates an exemplary application of the narrowband analysis;

FIG. 22 illustrates an exemplary application of the narrowband analysis and particularly an application of a curve fit technique;

FIG. 23 illustrates a portion of an exemplary baseline emission signature and a portion of the emission signature of the electrical device of FIG. 8 after irradiation;

FIG. 24 illustrates a portion of an exemplary baseline emission signature and a portion of the emission signature of the electrical device of FIG. 8 after irradiation;

FIG. 25 illustrates a portion of an exemplary baseline emission signature and a portion of the emission signature of the electrical device of FIG. 8 after irradiation;

FIG. 26 illustrates a portion of an exemplary baseline emission signature and a portion of the emission signature of the electrical device of FIG. 8 after irradiation;

FIG. 27A illustrates a transition of RF signature of the 2.5 MHz harmonic at each iteration dose of a beta type radiation;

FIG. 27B illustrates a transition of RF signature of the 2.5 MHz harmonic at each iteration dose of a gamma type radiation;

FIG. 27C illustrates a transition of RF signature of the 2.5 MHz harmonic at each iteration dose of a beta and a gamma type sequential radiation;

FIG. 28A illustrates a transition of RF signature of the 1.667 MHz harmonic at each iteration dose of a beta type radiation;

FIG. 28B illustrates a transition of RF signature of the 1.667 MHz harmonic at each iteration dose of a gamma type radiation;

FIG. 28C illustrates a transition of RF signature of the 1.667 MHz harmonic at each iteration dose of a beta and a gamma type sequential radiation;

FIG. 29 illustrates an exemplary total power metric within a frequency region;

FIG. 30 illustrates an exemplary power density function (PDF) of a total power metric within a 32 kHz frequency region as a heat map;

FIG. 31 illustrates an exemplary 2-D probability distribution; and

FIG. 32 illustrates an exemplary probability distribution for estimating degree of radiation exposure vs. probability for a given RF unintended emission metric.

### DETAILED DESCRIPTION

Prior to proceeding to the more detailed description of the present subject matter, it should be noted that, for the sake of clarity and understanding, identical components which have identical functions have been identified with identical reference numerals throughout the several views illustrated in the drawing figures.

It is to be understood that the singular forms “a,” “an,” and “the” include plural referents unless the context clearly dictates otherwise or expressly specified otherwise. Thus, for example, reference to “a component surface” includes reference to one or more of such surfaces.

For purposes here, the conjunction “or” is to be construed inclusively (e.g., “a dog or a cat” would be interpreted as “a dog, or a cat, or both”; e.g., “a dog, a cat, or a mouse” would be interpreted as “a dog, or a cat, or a mouse, or any two, or all three”), unless: (i) it is explicitly stated otherwise, e.g., by use of “either . . . or,” “only one of,” or similar language; or (ii) two or more of the listed alternatives are mutually exclusive within the particular context, in which case “or” would encompass only those combinations involving non-mutually-exclusive alternatives.

For purposes here, the words “comprising,” “including,” “having,” and variants thereof, wherever they appear, shall be construed as open-ended terminology, with the same meaning as if the phrase “at least” were appended after each instance thereof.

The verb “may” is used to designate optionality/noncompulsoriness. In other words, something that “may” can, but need not.

Before elucidating the subject matter shown in the Figures, the present disclosure will be first described in general terms.

Electrical devices are employed in a variety of applications. Electrical devices may include an electrical device. Electrical devices may include an assembly of electrical devices. The electrical device may be manufactured from a semiconductor material. The semiconductor material may include any one of silicon, graphite, and germanium. The electrical device may be available in a microelectronic equivalent suitable for a surface mount application. This may include a transistor, a capacitor, an inductor, a resistor, a diode, an insulator, and a conductor.

The electrical device may be an integrated circuit (IC). IC, also called microelectronic circuit, microchip, or chip, an assembly of electrical devices, is generally fabricated as a single unit, in which miniaturized active devices (e.g., transistors and diodes) and passive devices (e.g., capacitors and resistors) are interconnected and built up on a thin slice of a semiconductor material.

The electrical device may be a microcontroller. The microcontroller may be used as a central hub for computing operations, communication, and signal processing. The microcontroller may be used as space grade digital output temperature sensor.

The electrical device may be a binary counter. Binary counter applications may include a general timing application. Binary counter applications may include tracking the timing of bit streams for each input. Binary counter applications may include taking in multiple complex inputs and compression to four timed outputs. Binary counter applications may include filtering of bit streams.

The electrical device may be a shift register. The shift register may use cascading flip flops to support a variety of digital circuits. The shift register may be used to convert from serial and parallel interfaces. The shift register may be used to create simple delay circuits. The shift register may be used for utilization of a stack, such First In, First Out (FIFO). The shift register may be used in bit stream filtering. The shift register may be used in timing of communication circuits.

The electrical device may be a field-programmable gate array (FPGA).

The electrical device may be a processor.

The electrical device may be a metal-oxide-semiconductor field-effect transistor (MOSFET).

The electrical device may be a complementary metal oxide silicon (CMOS) transistor.

The electrical device may be a circuit assembly.

The electrical device is designed to perform a function. The electrical device may be designed to output a signal at an output pin. This signal may be referred to as an output signal. The output signal may be generated when the electrical device is energized. The output signal may be generated when the electrical device performed a designed function. The output signal may be a voltage. The output signal may be a current. The output signal may be a wave. The output signal may be a wave with a specific RF frequency. The output signal may be a combination of any one of the voltage, the current, and a sinusoidal wave.

The electrical device may be exposed to stress during operation or use. The stress may be related to an irradiation that the electrical device must function within and may be referred to as an irradiation stress. The irradiation stress may be related to exposure to radiation. The electrical device may be exposed to radiation in outer space applications. The electrical device may be exposed to radiation in applications within or near nuclear reactors. The electrical device may be exposed to radiation in applications within or near particle accelerators. The electrical device may be exposed to radiation during nuclear incidents. The electrical device may be exposed to radiation during nuclear warfare.

The electrical device may be stressed by an exposure to radiation.

Radiation may be due to operation of the electrical device in an outer space. Space radiation can be persistent and at a constant and predictable intensity or be random, unpredictable, and highly intense.

The electrical device may be exposed to galactic cosmic rays (GCRs), consisting of protons, electrons, and ionized heavy nuclei. The electrical device may be exposed to charged particles (mainly protons and electrons) trapped by planetary magnetic fields (e.g., Earth's Van Allen belts). The electrical device may be exposed to solar particle events (SPEs) that occasionally flood regions of space with large fluxes of energetic protons and heavier nuclei.

Radiation may be of an alpha radiation type. Radiation may be of a beta radiation type. Radiation may be of a gamma radiation type. Radiation may be of a neutron radiation type. Radiation may be of a high-energy type, such as ionic radiation. Radiation may combine two or more types.

Radiation may be persistent and at a constant intensity. Radiation may be unpredictable and of high intensity. Radiation of any type may be of different levels, values, or doses. Radiation of any type may be of different exposure intervals.

Electrical devices may be subjected to radiation hardening prior to use. Radiation hardening may refer to a process of making electrical devices and circuits resistant to damage of malfunction caused by high levels of ionized radiation, especially for environments in outer space.

When the electrical device is to be exposed to gamma radiation, the electrical device may be irradiated with 10 MeV of x-rays while being positioned closer to the accelerator. For a radiation dose of 5 krad, this mode may require 2 minutes of exposure time. For a radiation dose of 100-300 krad, this mode may take 39-117 minutes respectively.

When the electrical device is to be exposed to beta radiation, the electrical device may be irradiated with 6 MeV electrons. For a radiation dose of 5 krad, this mode may require 1 minute of exposure time. For a radiation dose of 100-300 krad, this mode may take 14-42 minutes respectively.

When the electrical device is to be exposed to gamma radiation, the electrical device may be irradiated with 18 MeV of x-rays. This mode may be characterized by a large time exposure than the previous two mode above.

A parameter of the electrical device may be monitored at each radiation dose and/or type. A functional test may be also performed at each radiation dose and/or type. The parameter may be selected as an output of the electrical device.

One or more radiation doses may be chosen for testing. One or more radiation types may be chosen for testing. Different radiation types may be applied individually or in a combination with each other. The test may continue until the parameter does not change at the next iteration.

The stress may be related to accelerated irradiation of the electrical device.

Exposure to the stress may degrade functionality of electrical devices. Electrical devices may need to function when being in a stressed condition. In a case of a radiation stress, the electrical device may need to successfully operate and survive in a persistent beta radiation environment and/or a persistent gamma radiation environment. Electrical devices may have to withstand the effects of radiation. In an application with bit streams, the induced radiation degradation may cause the electrical device to miss messages. In an application with bit streams, the radiation may add noise to an incoming signal, thus increasing a bit error rate of the electrical device design.

It may be necessary to identify effects of the stress onto operation and/or life of the electrical device. When the electrical device is to be used in an outer space application, it may be useful to identify doses and/or type of radiation where the operation of the electrical devices degraded and is outside of designed parameters. Identification may be by way of testing the electrical device being exposed to stress. Performance of the electrical device may be tested with different doses and types of the stress.

Identification of stress effects onto operation of the electrical device may be carried out by way of monitoring a condition of the electrical device during its operation. Monitoring the condition may include measuring a parameter of the electronic device at preselected intervals and comparing each measurement against a baseline measurement. Measurements may be plotted when manufacturer specification for a given electrical device includes a tolerance curve for the parameter being monitored.

Every electrical device gives off electromagnetic emissions when operating or when being simply energized into a powered state where the electric energy from an energy source is connected to various circuits and/or components within such electronic device. When the electrical device is simply powered on, the electromagnetic energy emanates from any one of wires, inter-component connections, and junctions within the electronic device. When the electrical device is energized, current flows through internal circuitry of the electrical device. Current flow changes through the circuitry generates emissions of electromagnetic energy. It may be sufficient to energize the electrical device by connecting an energy source to a power pin of the electrical device to generate unintended emissions. The energy source may be referred to as a power supply.

In this document, unintended emission(s) may be considered herein to be not only emissions emitted unintentionally by the electrical device contrary to the intent and objective of the electrical device, but also unintended properties of intended emissions of the electrical device. Unintended emissions refer to electromagnetic energy that is captured and analyzed which is not directly produced by the intended functionality of the electrical device. Conversely, intended emissions refers to electromagnetic energy that is captured and analyzed which is a direct result of the intended functionality of the electrical device, such as for example the carrier signal of an FM transmitter. Therefore, the intended digital data contained in an intended digital transmission would not be considered unintended, however other aspects of the intended signal such as harmonics, phase noise, frequency stability, out-of-band signal content, amplitude deviation, bit duration times, etc. could be deliberately used by the system for information content to be conveyed to the user.

Exemplary embodiments operate by analyzing the unintended and/or intended emissions of the electronic device.

Emissions phenomenology, especially unintended emissions, is causally dependent on an internal circuitry of the electrical device, layout of ICs and traces, material composition, physical state of the device, firmware and software operating on the device. The emission(s) of electromagnetic energy may be in a Radio Frequency (RF) spectrum, which is typically referred to in the art as frequencies above 3 kHz and below 300 GHZ. This emission may be referred to as an RF emission. Infrared, infrasonic, and other emissions may be also contemplated by the exemplary embodiments.

The forgoing description may be focused on intended emissions, unintended emissions and unintended features of intended emission(s) of electromagnetic energy. Electromagnetic energy may be in a radio frequency (RF) spectrum.

Emission phenomenology may manifest as an emission signature in a time domain. Emission phenomenology may manifest as an emission signature in a frequency domain. Emission phenomenology may manifest as an emission signature in both time and frequency domains. The emission signature may be classified by identifying an emission signature parameter or a characteristic.

The parameter may be chosen as a characteristic of RF emission signal. This parameter may be referred to as an emission signature parameter. The emission signature parameter may include a frequency. The emission signature parameter may include a wavelength. The emission signature parameter may include an amplitude. The emission signature parameter may include a phase. The emission signature parameter may include a peak width. The emission signature parameter may include a Full-Width-Half-Maximum (FWHM). The emission signature parameter may include harmonic indices. Emission signature parameter may include a harmonic spacing. The emission signature parameter may include a peak position. The emission signature parameter may include a peak skewness. The emission signature parameter may include a cross modulation peak parameters, The emission signature parameter may include a magnitude of the noise floor. The emission signature parameter may include power differences between peaks. The emission signature parameter may include a frequency shift of emissions. The emission signature parameter may include a Harmonic correlation (changes in harmonic content spacing, envelope, etc.). The emission signature parameter may include non-linear mixing products appearance, disappearance, relative spacing and envelope evolution. The emission signature parameter may include a time correlation (the substantially repeated pattern of evolution of signatures over time). The emission signature parameter may include a change in total emission energy. The emission signature parameter may include a change in emitted energy distribution symmetry and information content (Shannon Entropy). The emission signature parameter may include a non-harmonic signature correlation.

The emission signature parameter may include any combination of the above described emission parameter types. Emission signature parameter may be referred to as emission signature element.

The electrical device may be tested by analyzing an emission of electromagnetic energy in RF spectrum.

The analysis may focus on more than one parameter of the RF emission. The parameter may be chosen as an output signal at an output pin of the electrical device. The parameter may be chosen as a functional performance of the electrical device at each iteration. Functional performance of the electrical device may be tested at each iteration. Functional performance testing may include determination of whether or not stress changed functional performance. The test may continue until the electrical device has been stressed with all relevant or predetermined doses or levels. The test may continue until the electrical device exhibits changes in the electrical device's operation or emissions. The changes in the electrical device may include general tolerance allowances from part design to function degradation due to stress.

The parameter of the electrical device not exposed to stress may be chosen as a baseline parameter when an operation of the electrical device is not modified from its original design and when the electrical device is not stressed by external factors. The same parameter of the electrical device exposed to stress may be compared with the baseline parameter.

The testing may be performed by testing the electrical device in a fixture. The fixture may be referred to as a test fixture. The fixture may be designed with a socket to receive the electrical device. The fixture may be designed as a test device that is coupled to the electrical device via connectors. This design may be suitable to test a board-level assembly.

The fixture may be designed to energize the electrical device. The fixture may be designed to energize the electrical device with a power signal connected to a power input pin of the electrical device. The power signal may be provided as a voltage supply. The power supply may be provided through a step-down transformer when the electronic is designed to operate at a lower voltage than a voltage available from a power grid. The power signal may be provided as a power supply with a modulation, i.e. modulated power input. Modulated power input may help to generate additional signature characteristics as well as provide a known source of signal for examination of part functionality changes.

The fixture may be designed to energize the electrical device with a clock signal connected to a clock input pin of the electrical device. The clock signal source may be generated an external oscillator. The clock input may be provided as a sinusoidal input. The clock input may be provided as a high precision oscillator sinusoidal input, using a high precision clock as a clock signal source. The clock input may be provided as a high precision oscillator sinusoidal input, using a rubidium clock as a clock signal source.

The fixture may be designed to energize the electrical device with a combination of a power signal and a clock signal, as described above. The fixture may be designed to energize the electrical device with a combination of a power signal and a coded instruction to utilize an internal oscillator function of the electrical device. In an example, a microcontroller is typically designed with an internal oscillator.

The fixture may be positioned within a hollow interior of a shielded enclosure during test of the electrical device. The shielded enclosure may shield the electrical device from external noise during testing. The shielded enclosure may reduce influence of a noise external to the enclosure from affecting capture of RF emission. The shielded enclosure may eliminate influence of a noise external to the enclosure from affecting capture of RF emission.

A plurality of electrical devices may be irradiated within the chamber. Each electrical device from the plurality of electrical devices may be removed from the chamber at a different time from removal of other electrical devices for analysis of their RF emission. This arrangement provides for an incremental or iterative analysis to determine the effects of irradiation onto the electrical device. The incremental analysis may also be used to determine an age of the electrical device associated with the loss of functionality.

The analysis may include capturing the RF emission. The RF emission may be captured while the electrical device is positioned within the fixture and energized, as described above. The fixture may be positioned within an irradiated chamber during testing of the electrical device. In other words, the RF emission may be captured during changing conditions within the irradiation chamber. The RF emission may be captured while the electrical device is positioned within the irradiation chamber and energized, as described above. The RF emission may be captured while the electrical device is positioned within the irradiation chamber, energized and cycled, as described above.

The RF emission may be captured as a raw signal with an antenna. The antenna may be integrated into the shielded enclosure. The antenna may be integrated into the irradiated chamber. The analysis includes converting the raw signal into a digital signal. Conversion may be performed by a receiver coupled to the antenna. The analysis includes processing a signature of the digital signal. The processing may be performed by a signal processing unit coupled to the receiver. The receiver and the signal processing unit may be integrated into a single unit. The receiver and the signal processing unit may be designed and provided independently from each other.

The receiver may be disposed within the shielded enclosure. The receiver may be disposed external to the shielded enclosure. The signal processing unit may be disposed within the shielded enclosure. The signal processing unit may be disposed external to the shielded enclosure. The receiver may be disposed within the irradiated chamber. The receiver may be disposed external to the irradiated chamber. The signal processing unit may be disposed within the irradiated chamber. The signal processing unit may be disposed external to the irradiated chamber.

The receiver may be designed with a sensitivity of a −145 decibel-milliwatts (dBm). The receiver may be designed with a sensitivity of a −150 decibel-milliwatts (dBm). The receiver may be designed with a sensitivity of a −160 decibel-milliwatts (dBm). The receiver may be designed with a sensitivity of a −170 decibel-milliwatts (dBm).

The receiver may be designed with a low noise amplifier (LNA). The LNA may be coupled directly to the antenna. The LNA may have a noise factor of under 2 dB. The LNA may be designed or selected to operate within a specific range, for example between 40 MHz and 100 MHz or within any increment thereof. The LNA may also operate at frequencies below 40 MHz or above 100 MHz.

The receiver may be designed with a filter disposed between the antenna and LNA and designed and operable to pass a specific or desired frequency range or band from the antenna to the LNA and at least reduce if not completely eliminate saturation, clipping and/or distortion of the signal from the antenna to the LNA. The filter may be a band pass filter. The filter may be an LC circuit. The filter may be a ceramic resonator, configured or selected to operate in a specific frequency range. The filter may be a band-stop filter configured to eliminate an undesired band of frequencies, a low-pass filter configured to allow passage only of frequencies below cut-off frequency or high-pass filter configured to allow passage only of frequencies above cut-off frequency.

The receiver may be designed with an analog to digital converter (ADC). The ADC may be designed and operable to transform received analog signal from the LNA to digital signal for further analysis and processing by the signal processing unit.

The receiver may be designed with a filter disposed between the LNA and ADC. This filter may be provided as a selectable filter bank. The selectable filter bank may comprise one or more filters, each configured and operable to separate the frequency signal from the LNA into components. Each component carrying a single frequency sub-band of the frequency signal.

The signal processing unit may be a computer. The signal processing unit may be designed as a custom controller. The signal processing unit may be designed with the FPGA. The signal processing unit may be designed with a processor and a non-transitory tangible computer readable medium and/or tangible computational medium comprising algorithms and/or executable instructions (computer program code) that when executed by the processor cause the processor to perform various method steps as disclosed in this document. The instruction may include instructions to process the signal in a frequency domain. The instruction may include instructions to process the signal in a time domain. The signal processing unit may be designed as a combination of the FPGA, the processor and the non-transitory tangible computer readable medium and/or tangible computational medium.

Tangible computer readable medium means any physical object or computer element that can store and/or execute computer instructions. Examples of tangible computer readable medium include, but not limited to, a compact disc (CD), digital versatile disc (DVD), blu-ray disc (BD), usb floppy drive, floppy disk, random access memory (RAM), read-only memory (ROM), erasable programmable read-only memory (EPROM), optical fiber, etc. It should be noted that the tangible computer readable medium may even be paper or other suitable medium in which the instructions can be electronically captured, such as optical scanning. Where optical scanning occurs, the instructions may be compiled, interpreted, or otherwise processed in a suitable manner, if necessary, and then stored in computer memory.

Alternatively, it may be a plugin or part of a software code that can be included in, or downloaded and installed into a computer application. As a plugin, it may be embeddable in any kind of computer document, such as a webpage, word document, pdf file, mp3 file, etc.

Analysis of the emission signal may be performed on a digitized emission waveform, as may be exhibited by a spectrum analyzer. The spectrum analyzer may be designed as a combination of a circuit assembly and a display. The user may use the display to visually select RF signature parameter of interest from the waveform. The user may use the display to visually select a frequency region of interest from the waveform. The signal processing unit may be designed with the spectrum analyzer. The signal processing unit may be designed to output the waveform as a print file.

In this document, functionality of the electrical device may be described as a working condition of the electrical device, and may be referred to as operational, irradiated to a degree, likely to imminently fail, or beyond useful life. Operational here may mean that the electrical device is in full specified working order, with no functional hardware flaws and fully functioning subcomponents. Altered or additional functionality may refer to deviations from operational status that damage, degrade, or otherwise change the performance of the electrical device. A comparison may be made to a baseline measurement of a known electrical device with designed functionality and being in an unaltered condition.

Analysis may include frequency changes of a modulated signal where the modulating signal's frequency in occurrence for a given time interval. This frequency change may be observed as a measured spacing between the side band peaks shown in the figure. A signal change may be related to an alteration of a clean precise clock frequency, where as a clock ages in the case of an oscillator or degrades in other cases, the shape of the resulting clock harmonics in the frequency domain will undergo two changes. The first change is that the base of the frequency signal will widen because of increased phase noise, while the second is a movement of the harmonic peak in absolute frequency. For the case of crystal oscillators, the frequency of the clock will change with irradiation on a small scale (kHz), which is magnified as the harmonic index increase (as absolute frequency position increases). For other cases of degradation, the clock signal may degrade from one state to a new state, resulting in a dramatic change in the RF spectrum and in part functionality.

The electrical device may be tested by capturing and analyzing RF emissions in a frequency domain.

The electrical device may be tested by measuring/determining an operational output from the electrical device in a time domain.

The electrical device may be tested by capturing and analyzing RF emissions in a frequency domain and measuring/determining an operational output from the electrical device in a time domain.

Analysis of captured RF emission data may provide a threshold indication of transition and/or an evolution of degradation as doses of the irradiation stress increase and effects of the exposure to the irradiation stress accumulate.

The analysis may include identifying changes in the designed output as measured on the output pin. The analysis may include measuring changes in the designed output at the output pin. When the output is chosen for analysis, the output at the output pin may be monitored for toggling between the intended duty cycle and a new unintended duty cycle. When the output is chosen for monitoring, the output may be monitored for a change as radiation dose increases. When the output is chosen for monitoring, the baseline steady state output may be monitored for a change to a new state where the output toggles between the intended duty cycle and a new unintended duty cycle. Change to the new state may indicate a degraded performance of the electrical device. When the output is chosen for monitoring, the output may be monitored for stabilizing at the applied radiation dose where the output will not change due to stress of the electrical device with a next higher dose or level. In an example of a radiation degraded shift, functional performance testing may include a determination of whether or not the radiation degraded shift register misses data events in operation resulting in incorrectly shifts data bits. In an example of a radiation degraded shift, functional performance testing may include determination of whether the radiation degraded shift register is associated with an increased bit error rate.

Degraded performance may include an output voltage that is above or below a designed range. Degraded performance may include an output frequency that is above or below a designed range. Degraded performance may include an output frequency that fluctuates in a new range between a first value outside of a designed lower range value and a second value being outside of a designed upper range value and is thus unstable. Degraded performance may include an output frequency that drifted from its fundamental value. Degraded performance may include a change in the envelope of an output signal waveform. Degraded performance may include a change in the threshold input voltage limits that determine or define a ‘1’ or ‘0’ value. Degraded performance may include a change in output voltage or current capability. Degraded performance may include a change in leakage current.

The output may be monitored in a time domain. The output may be monitored in a frequency domain. The output may be monitored in both time domain and frequency domain.

In the frequency domain, an absolute frequency position in the waveform may be measured by indicating the frequency value of the highest point of a peak or structure from a given spectrum. For harmonic outputs, an exact value of the position may aid in determining if a peak or structure belongs to a harmonic series. A harmonic series is defined by a fundamental value, this fundamental value is the first frequency value in the series. For example, for a harmonic series where the fundamental is 2.5 MHz the first peak in this series will appear at the frequency value of 2.5 MHz in a spectrum graph. Other peaks in the harmonic series are defined as indices multiples of the fundamental, for example 35 MHz is part of the 2.5 MHz harmonics series since 2.5 MHz times 14 is 35 MHz, while a peak at 35.3 MHz would not be a part of the 2.5 MHz harmonic series since 35.3 MHz divided by 2.5 MHz is not an index value. Furthermore, it is noted that the frequency difference, that may be referred to as delta “f”, between two harmonic peaks will be that fundamental value. The measurement from peak to peak in this case is an absolute difference from one absolute frequency position to the next. It is noted that evenly spaced peaks may not belong to a harmonic series where the spacing value X divided into the absolute frequency position of a given peak does not produce an index value. This set of evenly spaced peaks may be caused cause by another phenomenon.

Analysis of RF emissions from a stressed electrical device may be used to determine an operational threshold at a given dose or level of the stress. The operational threshold may be defined by a requirement that the output frequency does not toggle (change) to a new state. The operational threshold may be defined by a requirement that the output frequency may toggle to a new state where this new state is sufficient for at least limited operation of the circuit employing the electrical device.

While a single wideband frequency scan may be used to gain a high-level understanding of the effects of the irradiation, a repeated narrowband frequency scan may be performed on a frequency region over a period of time to gain more acuity on states of the output frequency.

A resolution bandwidth of the scan may be selected as 0.1 seconds. A resolution bandwidth of the scan may be selected as 1 second.

The signal processing unit may be designed to execute a curve fit algorithm on the emission signal. Spectral emissions from electronics are very rarely spectrally pure. Phase noise and jitter are two examples in real-life systems that force emissions in the frequency domain to have shape. This may be evident at the base of the emissions signature and the higher the sensitivity of the system the more this effect is prevalent.

Curve fit algorithm may be used to measure a peak amplitude at the center of a peak curve. Curve fit algorithm may be used to measure, in a frequency domain, a shape of a peak curve in a digital waveform of an emission signal. Curve fit algorithm may be used to measure, in a frequency domain, an area under a peak curve in a digital waveform of an emission signal. Curve fit algorithm may be used to measure, in a frequency domain, a shrinking of the curve over time. Curve fit algorithm may be used to measure, in a frequency domain, the sharpness of a peak curve in a digital waveform of an emission signal.

A curve fit algorithm may be utilized to investigate toggling of the output frequency states. The curve fit algorithm may discern a kurtosis outlier, an area under a curve outlier, and a selected width outlier to examine changes of the RF spectrum in a transition state of the output frequency between exposure to two subsequent levels of the stress. Curve fit may provide a measure of phase noise or jitter evolution as the electrical device is exposed to stress and ages or degrades as the result of the exposure.

The signal processing unit may be designed to extract metrics of the harmonically related emissions of the electrical device. The emission may be related to a clock of the electrical device. The emission may be related to switching metal-oxide-semiconductor field-effect transistor (MOSFET). The signal processing unit may be designed to execute a harmonic analysis. The character of the harmonic content and the fall-off of the harmonics are directly related to the shape of the clock or the digital waveform an electronic system generates. As the electrical device ages or degrades, the propagation of the clock through the electrical device due to degradation or irradiation of the junctions of the electrical device may cause the rise time or fall time slope of a waveform to become rounded, which results in a fall off the harmonic spectrum.

The signal processing unit may be designed to execute a non-harmonic analysis. The electrical device may be designed with numerous blocks of circuits (IP blocks in ICs) that have different functions and often reference different signals. By measuring the drift of signatures of one block compared to other blocks it may be possible to gain insight into how circuits are degrading.

The signal processing unit may be designed to execute a time correlation algorithm. The emission signature may drift over time. Time correlation algorithm may be used to determine a consistently related frequency or amplitude drift of any two adjacent peaks in a digital waveform in the time or frequency domain of an emission signal. Time correlation algorithm may be used to determine a drift of a peak in a digital waveform of an emission signal over time. Time correlation algorithm may be used to determine a location of a first peak with a baseline frequency location and then its subsequent frequency change and correlate this change to a second peak's frequency drift.

Depending on the underlying circuit design, the emission frequency may drift from its specified fundamental frequency. A change in the drift may be indicative of irradiation. A change in the drift may be indicative of degradation of the underlying electronics. Measuring and tracking the drift may be used as a measurement of degradation.

Frequency drift may be specified as a frequency tolerance for the electrical device. The tolerance may be specified as a curve. Plotting of a measured drift versus tolerance drift may aid in determining a remaining useful life (RUL) condition of the electrical device or the accumulated irradiation dose.

Time correlation may also provide a view into functionality of the electrical device. In this technique, the duration of time at which the output frequency may be in a toggling state until a new output frequency stabilizes is identified.

The time correlation may be used to establish an operational or a functional threshold for the electrical device. The threshold states of the electrical device may be used to improve a functional design of the electrical device when used in circuit applications. The threshold states of the electrical device may be used to design a circuit or improve a design of an existing circuit that may only operate at a lower output frequency than desired. The threshold states of the electrical device may be also used to determine applications where a given electrical device may not be used by comparing a dose of the irradiation stress that the circuit may be exposed against testing of the electrical device at that specific dose.

The signal processing unit may be designed to analyze non-linear products (NPLs) which may arise from within the electrical device that comprises non-linear mixing of emission signals from the two adjacent traces in a time domain and then measuring a frequency modulation of the resulting emission. NLPs are sometimes the result of unintended non-linear mixing of signals within an electrical device or an assembly (board) of electrical devices due to their interaction with other clocks or signals within the device. One mechanism for NLPs may be a cross modulation, which occurs when two nearby wire traces carrying different signals interact. Crosstalk is induced when both signals are active, causing a modulation between a lower-frequency signal and a higher frequency signal. Modulation may be related to an unintended amplitude modulation in the waveform. Modulation may be related to an unintended frequency modulation in the waveform. Modulation may be classified as amplitude modulation or frequency modulation.

A non-linear product can be briefly described by three parameters:
The carrier frequency, f_{c}—a clock or other propagating primary signal being unintentionally modulated by another electrical signal within the electrical device, the carrier frequency may be also a frequency of a central peak;
The modulation frequency, f_{mod}—which is also the spacing between peaks; and
The number of peaks, n.

NLP extraction algorithm may be designed to search the broadband spectrum for sets of peaks that fit this description and report the list of found NLPs to the user. The algorithm may also report the results to other software processing modules for further examination, processing and use which may include extracting metrics and statistics on the NLPs found such as number of peaks above noise floor, dB height of peaks, spacing of peaks, dB height relationships between peaks, and/or changes in the preceding over short or longer periods of time. If the user selects an NLP from a list, its components may be identified visually on the displayed spectrum with a set of blue dots, and metric information extracted from that NLP may be displayed to the user. Additional metric information such as modulation indices (M-indices) may be also displayed. The user may then have the ability to sort, filter, or export the list of found NLPs.

A condition of the electrical device, such as RUL, may be determined by using a modified Bayes' equation (1):

$$P ( {RUL}_{i} \vert \{ S \} ) = \frac{{\prod }_{j = 1}^{m} P ( {S}_{j} \vert {RUL}_{i} )}{{\sum }_{i = i}^{n} 〈 {\prod }_{j = 1}^{m} P ( {S}_{j} \vert {RUL}_{j} ) 〉} \qquad Equation ( 1 )$$

where:
P—probability
R_{ULi}—particular RUL value
{S}—measured set of emission signature parameters
I—index of discrete RUL values considered
j—index of properties in the property set
n—the number of discrete RUL values considered
m—the number of properties in the property set

Individual probabilities may be based on the observed rate of change in signature metrics. Individual probabilities may be based on a mathematical function defining circuit degradation. Individual probabilities may be based on an estimate of error. Likelihood functions for each parameter may be based on afunctional deterministic relationship between that emission signature parameter and device circuitry state. The functional relationship captures the quantitative manner in which the parametric changes with the irradiation of the electrical device. Uncertainty in function coefficients and measurement values may be accommodated through the components of the probability calculation. These may take a form of a Gaussian function that assess the difference between what function coefficients according to the identified relationship and what those coefficients converge to resulting in an end of useful life value for the parameter given the measured value and a particular RUL. A Gaussian error estimate conforms to the Central Limit Theorem. The following equation (2) defines the likelihood function for a parameter:

$$P ( {S}_{j} \vert {RUL}_{j} ) = P ( {S}_{EUL} \vert {S}_{j} , {f}_{j} , {RUL}_{i} ) \qquad equation ( 2 )$$

where:
Sⱼ—measured parameter value
RULᵢ—particular RUL value
S_{EUL}—parameter value representative of the end of the useful life of the device
   fⱼ—function defining the relationship between the parameter value and device age.

A condition of the electrical device, such as RUL, may be estimated by first generating a Probability Density Function (PDF) map, then calculating PDF using a non-parametric kernel density estimation and calculating RUL.

PDF may be generated by first plotting a total power within a frequency region as a function of equivalent years of degradation and then generating a PDF map. The equivalent years of degradation may be estimated based on linear or non-linear extrapolations or interpolations from surrounding regions or data points.

Calculating PDF may be by using a non-parametric kernel density estimation. The basic kernel estimator is given below by equation (3):

$$\hat{f} ( x ) = \frac{1}{nh} {\sum }_{i = 1}^{n} K ( \frac{x - {x}_{i}}{h} ) = \frac{1}{n} {\sum }_{i = 1}^{n} {K}_{h} ( x - {x}_{i} ) \qquad Equation ( 3 )$$

where:

$${K}_{h} ( t ) = \frac{K ( \frac{t}{h} )}{h}$$

f(x)—density function
h—bandwidth or window width
n—number of points within the bandwidth
K—kernel
Kₕ—kernel K scaled by bandwidth h
(x−xᵢ)—Euclidean distance between each point i and the location where the density estimator is worked out center point of a cube
t—a point.

The kernel estimator is the arithmetic mean of n independent and identically distributed random variables. The kernel is then normalized to ensure that the probability is 1 when integrated over the entire function. At a given measurement of the metric, a 2-D probability distribution may be readily calculated and may provide a most likely value for RUL.

Once estimated device status is calculated, RUL can then be determined. A logarithmic functional relationship is determined, and for each potential parameter set the likelihood that those parameters describe the measured data is calculated. A 2-dimensional PDF may be created based on those likelihoods, with a 1-dimensional PDF calculated based on the amount of time the device has been aged.

In a degraded state, in the case of FIFO stacks, bits may be lost and the data may be corrupted.

In view of the above, in the case of the shift register being for the timing of communication circuits, those circuits may effectively exhibit failure characteristics due to degradation.

The document also describes a tool that provides an emission signature-based assessment of the effects of radiation doses on an electrical device.

Assessment may be related to a level of functional degradation of the electronic part operating in a radiation environment.

Assessment may be related to the remaining useful life (RUL) of the electronic part operating in an irradiation environment.

Assessment may be related to a degree of survivability of the electronic part operating in a radiation environment.

The tool may provide a low-cost approach to assess the effects of radiation doses on an electrical device's operation.

The tool may reduce the time interval required to assess the effects of radiation doses on an electrical device.

The tool may be used to determine the expected lifetime more accurately and/or replacement time of an electrical device subject to irradiation or atomic radiation exposure before the device fails.

The tool may reduce the time interval required to assess the effects of radiation doses on an electrical device.

The method, as described above, may be used to improve current radiation simulation modeling software for microelectronic and electronic circuitry design include applications, such as PSpice. Though PSpice allows modeling of specific semiconductors and transistors, as well as small circuits for radiation effects, the tool is very limited. The PSpice tool primary predicts to what degree components will be affected by irradiation but lacks precision to apply the capability to large complex circuitry like an entire system.

Irradiation estimation results (for example from a radiation exposed part such as from near a nuclear reactor) based on captured RF emissions may be correlated with irradiation exposure amounts using an accurate X-ray source of known wavelength and intensity where intensity is measured as Watts·mm⁻² or Joules·mm²·s⁻¹. Accordingly, metrics may be developed to define how the irradiation phenomenon corresponds to the RF emissions data.

The method, as described above, may be used in equipment for exploration of space.

The method, as described above, may be used in a military application.

Now in a reference to the drawings.

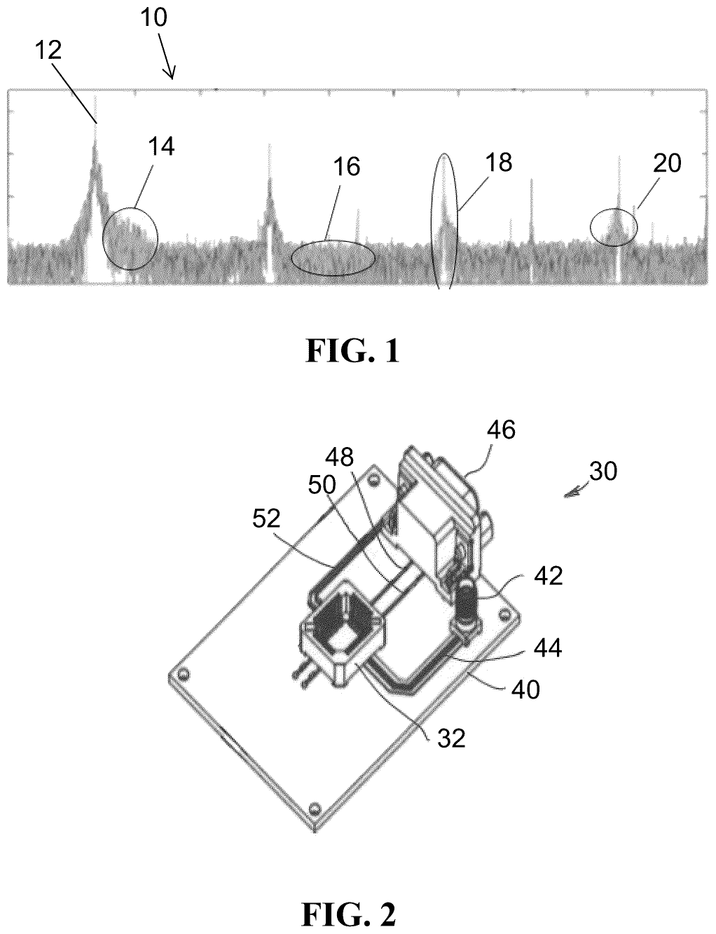

FIG. 1 illustrates exemplary parameters in the emission signature waveform 10. Particularly illustrated are peak amplitude (power) 12, skewness 14, noise floor 16, frequency location 18 and phase noise 20. The amplitude 12 may be measured in dB. The frequency values are along a horizontal axis in this and other figures. The amplitude values are along a vertical axis in this and other figures.

FIG. 2 illustrates an exemplary fixture 30 that may be designed to test electronic devices.

The fixture 30 may be designed to receive one or more electrical devices therewithin. When the electrical device is a semiconductor device, for example such as an integrated circuit (IC), the fixture 30 is designed with a socket 32, configured to mate with the electrical device. The socket 32 may be designed for insertion of the electrical device thereinto. The socket 32 may be designed to mate with the electrical device of a surface mount type. The socket may be mounted on a circuit board 40. The exemplary fixture 30 of FIG. 2 is illustrated as including a connector 46 and two connections between the connector 46 and the socket 32: a power connection 48 and a ground connection 50. An optional connection 52 between the socket 32 and the connector 46 may be also provided. The optional connection 52 may be connected to an output pin of the electrical device. The exemplary fixture 30 of FIG. 2 is further illustrated as including a clock connection 44 and a clock input connector 42.

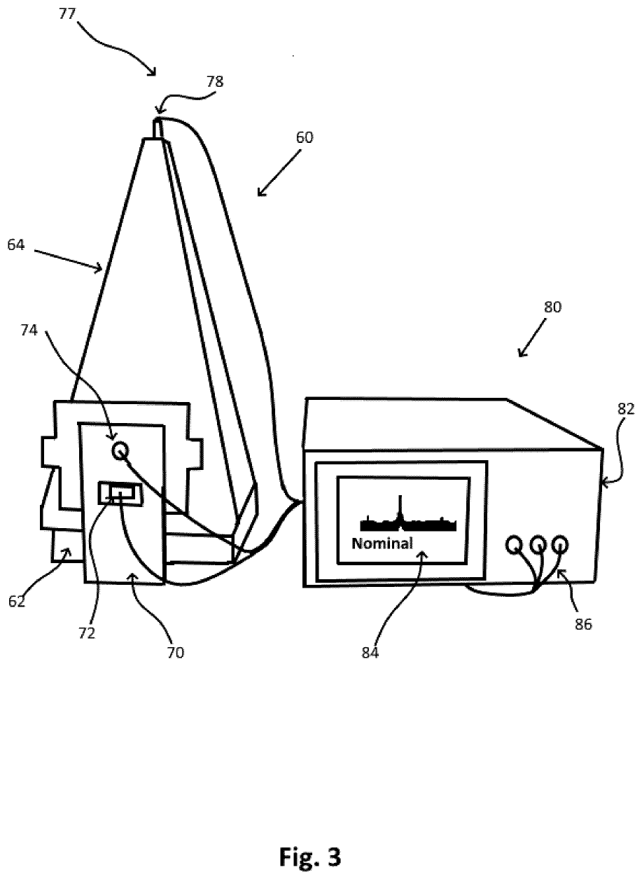

FIG. 3 illustrates a perspective view of an exemplary enclosure 60 and a device 80 combining a receiver 100 with a signal processing unit 120. The enclosure 60 is illustrated as being designed with a base 62 and a peripheral wall 64 upstanding on the base 62. The peripheral wall 64 may be designed with a pyramid shape, as is illustrated in FIG. 3. The peripheral wall 64 defines, in a combination with the base 62, a hollow interior of the enclosure 60. The enclosure 60 is illustrated as designed with a drawer 70 mounted for a movement, in a generally horizontal plane during use of the integrated enclosure 60, to selectively allow access into the hollow interior. A power/ground input connection 72 and a clock input connection 74 are provided on the peripheral wall 64 and, more particularly on the exterior surface of the drawer 70, by way of connectors. An antenna connector or fitting 78 is connected to an antenna internal to the enclosure 60 and is integrated into the enclosure 60 and is represented by an antenna fitting 78 at an apex of the peripheral wall 64. The antenna fitting 78 is connected to the device 80 and provides a connection so as to output the collected RF emission given off by a device which may be inserted into socket 30. Typically fixture 30 is placed inside enclosure 60 and connected to clock input connector 44 and power input 72 internally inside enclosure 60.

The device 80 may be designed with an enclosure 82, a display 84 and connections 86 to the enclosure 60. The display 84 may be provided as a graphical user interface (GUI) and may include a touch screen.

The drawer 70 may be designed to mount the fixture 30 on its interior surface. The drawer 70 may be also replaced with a door, for example such as a swing door, to allow access of larger electrical devices into the hollow interior of the enclosure 60.

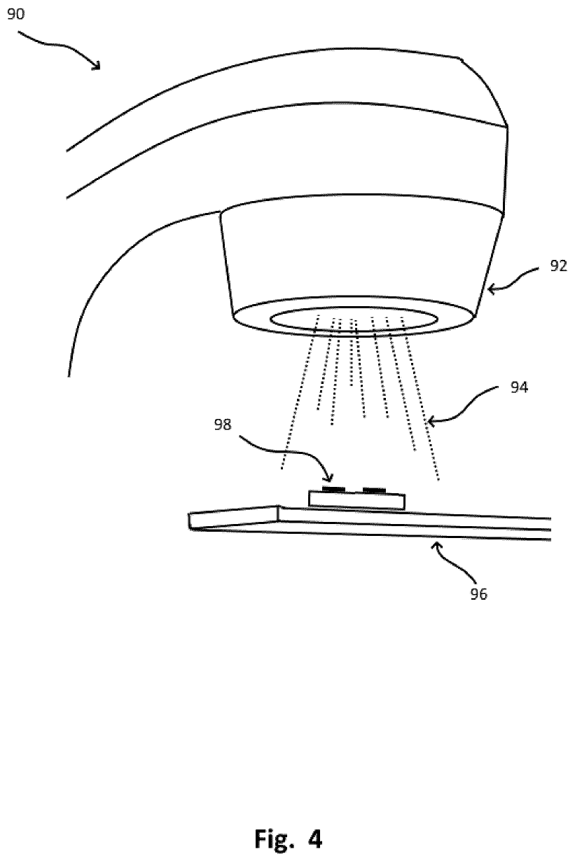

FIG. 4 illustrates an elevation view of an exemplary irradiating device 90 with a irradiating head 92 to allow radiation beam 94 into an electronic device 98 held by holding mechanism 96. The device 90 may be designed as an irradiation test chamber or device, wholly enclosed and electrically shielded or not enclosed as illustrated. Device 90 may be inside enclosure 60 or enclosure 60 may be inside device 90 or outside and simply within radiation beam 94. Alternatively, electronic device 98 may be separately irradiated by device 90 and then placed in enclosure 60 using fixture 30's socket 32.

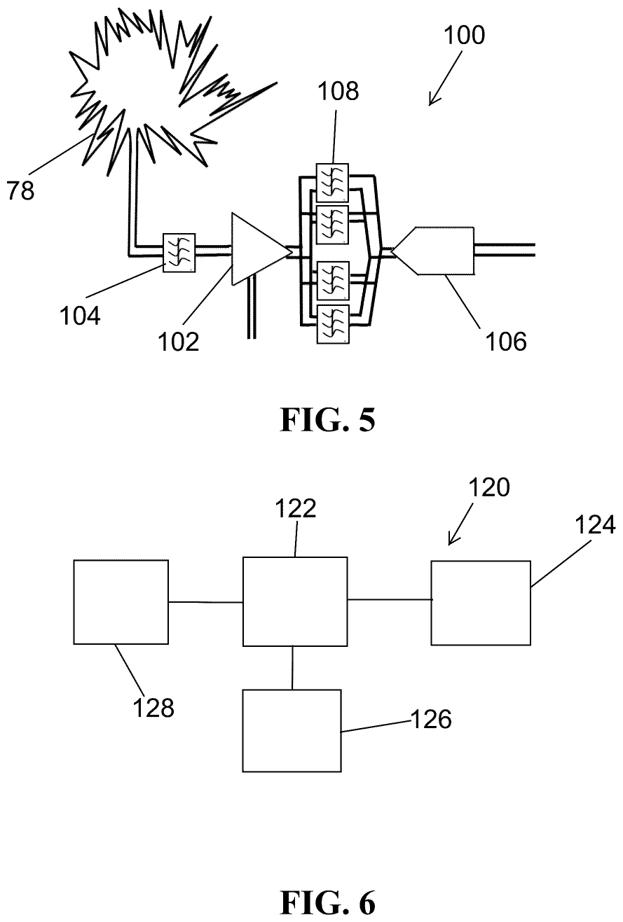

FIG. 5 illustrates a block diagram of an exemplary receiver front end 100. A low noise amplifier (LNA) 102 is mechanically and electrically connected to the antenna 78. A filter 104 may be positioned in a connection between the antenna 78 and the LNA 102. The LNA 102 is illustrated as being coupled to an analog-to-digital converter (ADC) 106. A filter 108 may be disposed in a connection between the LNA 102 and ADC 106. The filter 108 may be designed as a filter bank of a plurality of filters, as described above. Also, a pre-filter 104 may be applied before the LNA 102 to prevent strong interferer signals from entering the LNA 102 and distorting its amplification.

FIG. 6 illustrates a block diagram of an exemplary signal processing unit 120 with a processor 122, medium (memory) 124, a signal interface 126 and an optional spectrum analyzer 128.

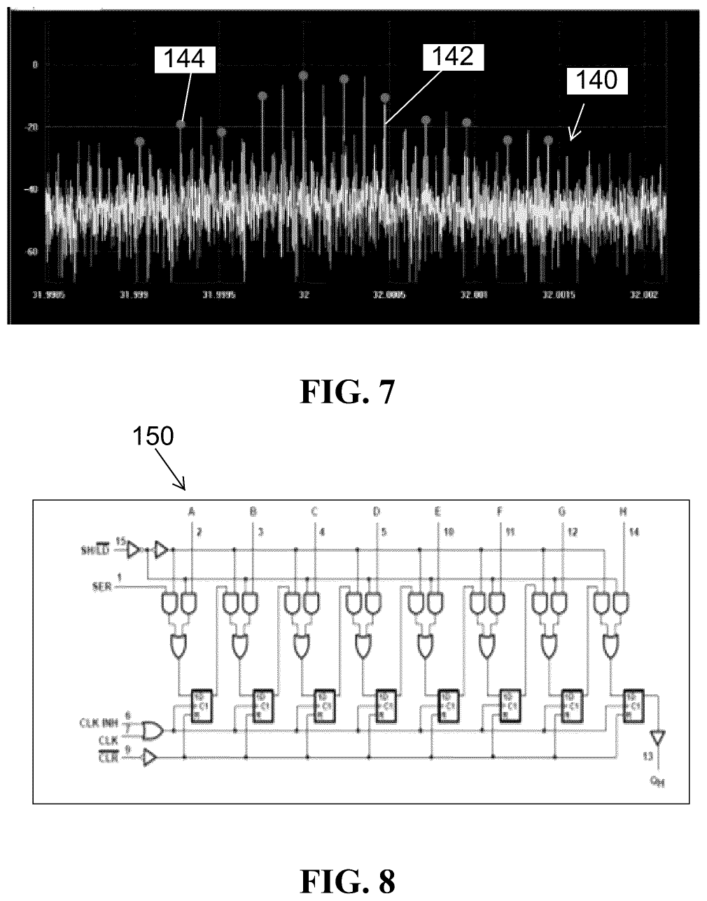

FIG. 7 illustrates an exemplary representation 141 of non-linear products 140 with components 142 identified visually on a displayed spectrum with a series of dots 144.

FIG. 8 illustrates a block diagram of an exemplary electrical device, such as a radiation hardened shift register 150 from Texas Instruments, under a part number 5962-9050101VEA also known as SNS54HC166-SP Parallel-Load 8-Bit Shift Register. The radiation hardened shift register, when energized with a 5 MHz high precision rubidium oscillator sinusoidal clock input and a power supply of 3.4 V (DC) with a 200 Hz modulation signal of 0.4V P-P applied to it, divides the input clock frequency by 2, and is be designed to output a 2.5 MHz square wave (400 ns duty cycle), 3V amplitude on the output Q_{H} pin. Furthermore, the radiation hardened shift register 150 may be provided to operate at different hardness doses or ranges.

FIG. 9 illustrates an exemplary clock input 160 applied to the radiation hardened shift register 150 of FIG. 8. The exemplary clock input 160 is illustrated as a 5 MHz sinusoidal clock input.

FIG. 10 illustrates an expected designed functional output signal 170 at Q_{H} pin from of the radiation hardened shift register 150 of FIG. 8. The expected designed functional output signal 170 is illustrated with digital voltage level ‘1’ components 172 and digital voltage level ‘0’ components 174.

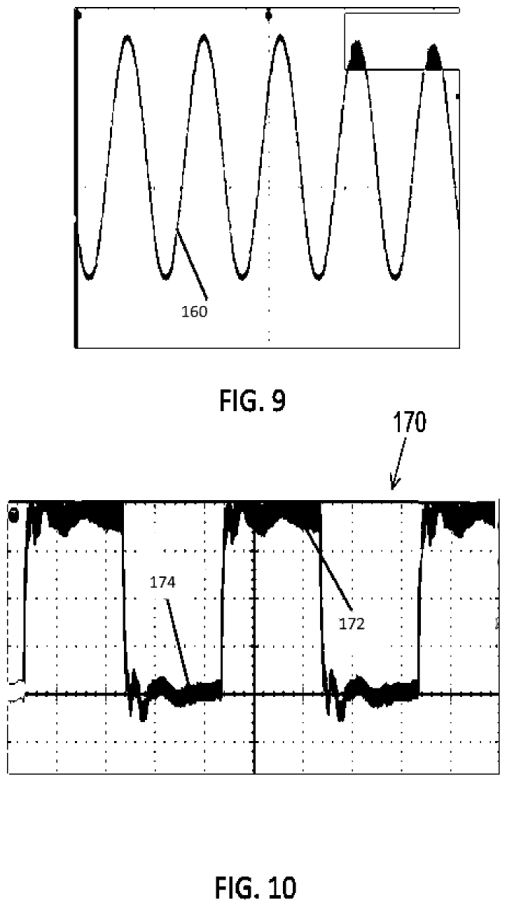

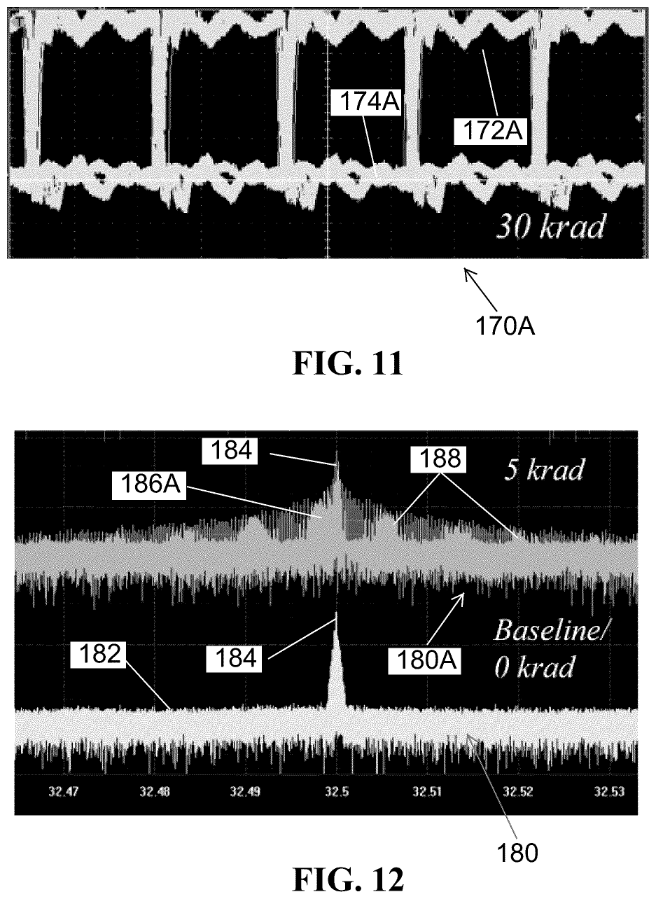

FIG. 11 illustrates unintended toggling features of the functional output 170 as observed in the time domain after irradiation of the radiation hardened shift register 150 with 30 krad of beta or gamma type. In an example of the radiation hardened shift register 150, different radiation doses may be sequentially (iteratively) applied based on design specifications. The doses of radiation hardness may include a 5 krad, a 30 krad, a 50 krad, a 100 krad and a 300 krad levels. The output of the radiation hardened shift register 150 at the output Q_{H} pin may be chosen for monitoring. FIG. 11 illustrates additional components 172A and 174A in the modified functional output 170A of the irradiated radiation hardened shift register 150.

FIG. 12 illustrates a portion of an exemplary baseline signature 180 of RF emission from the radiation hardened shift register 150 in a frequency domain. The baseline signature 180 may be defined by a peak 184 arising from a noise floor 182. FIG. 12 also illustrates a corresponding signature 180A in the same narrowband frequency region after irradiation of the radiation hardened shift register 150 by 5 krad of beta type radiation. FIG. 12 illustrates an example change of the output signal present at a selected harmonic of the 2.5 MHz output frequency showing a widened envelope 186A of the peak 184. FIG. 12 illustrates a change of the output signal present at the representative 32.5 MHz harmonic (represented by peak 184) of the 2.5 MHz output frequency that now has a widened envelope 186A and additional peaks 188. FIG. 12 also illustrates that there is no functional degradation effect to the output of the radiation hardened shift register 150, even though the peak 184 is changed. However, the change of the output signal reflected in FIG. 12 may provide an early indication that can be reported in advance of the functional degradation occurrence. Change of the output signal reflected in FIG. 12 may be also used for predictive modeling of degradation.

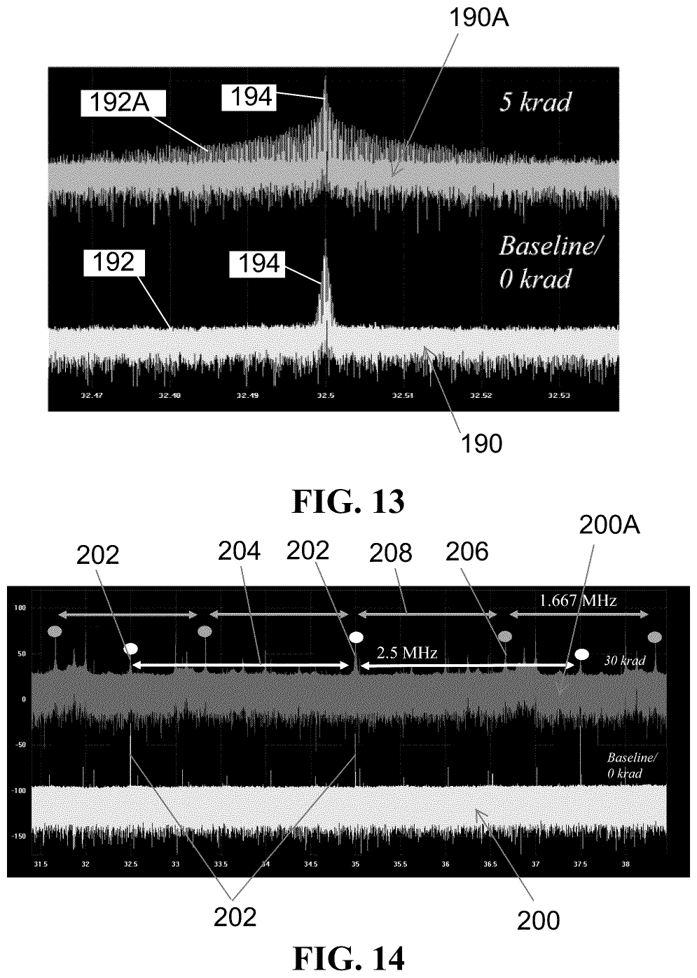

FIG. 13 illustrates a portion of an exemplary baseline signature 190 of RF emission in a harmonic narrowband region of frequency domain and a corresponding signature 190A after irradiation by 5 krad of gamma type radiation. As it can be seen, a change of the output signal (represented by a peak 194) of a 2.5 MHz output frequency harmonic at 32.5 MHz has a widened envelope. FIG. 13 also illustrates that the output of the radiation hardened shift register 150, as the peak 194 remains present. However, the change of the output signal reflected in FIG. 13 may provide an early indication that can be reported in advance of the functional degradation occurrence. Change of the output signal reflected in FIG. 13 may be also used for predictive modeling of degradation.

FIG. 14 illustrates a spectrum which may result from one or more out of specification, degraded, reduced functionality, or wholly defective gate or transistor within an integrated circuit (IC) not properly changing state from a ‘1’ to a ‘0’. Such modification in a component may result in modification of the overall functionality of the IC. Such modification may be slight such as a slightly higher threshold voltage or reduced sensitivity to a voltage level near the minimum voltage to be considered a ‘1’ value, and/or a wider metastable region for a gate between ‘1’ and ‘0’. Such a degradation may gradually worsen as the IC is exposed to more cumulative radiation exposure and this may cause sporadic glitches or malfunctions in the circuit when ever-present or expected noise in the circuit causes newly created narrower limitations to be exceeded. It may also cause it to not operate within specification which may or may not cause malfunction based on the circuit design it is in, for example well within the bounds of normal operation as contrasted with a circuit design much nearer the voltage limits boundaries of the specification. The degree of degradation may be observed by the spectrum created by the subject matter. The degree of degradation may be created by the subject matter by means such as varying the supply voltage to the part, parts, or system under test. The voltage variation may be in the form of a sine wave such as a sine wave of 200 Hz varying input voltage by 5% such as varying a 3 VDC input by 150 mV or 150 mV P-P or 2.925 V to 3.075 V. The voltage variation may be in the form of a sine wave such as a sine wave of 100 Hz varying input voltage by 25% such as varying a 3V input by 750 mV or 750 mV P-P or 2.675 V to 3.375 V. In this manner the part cycles between more extremes of specification voltage limits while operating under a clock frequency input and exhibiting more, differing, or exaggerated unintended features or artifacts of RF unintended emissions being radiated. For example, as the part degrades from irradiation, transistors or gates within the device may degrade leakage current characteristics, transconductance characteristics, reduce gain, or increase internal noise which changes circuit operation and may be observable in its RF emission features. Depending on circuit design, the correct operation of the device may be prevented, or sporadic errors may arise.

FIG. 14 illustrates RF emission output as observed in the frequency domain after irradiation of the radiation hardened shift register 150 in a circuit with 30 krad of beta or gamma type. The baseline emission signature 200 is defined by peaks 202 spaced therebetween by a designed output frequency 204 of 2.5 MHz. The modified emission signature 200a after irradiation by 30 krad now shows new frequency artifacts 208 of 1.67 MHz defined by new peaks such as 206 that were not present before irradiation.

This unintended emissions of 1.67 MHz harmonics is related to degradation of the operating parameters of transistors or gates devices within the IC within the circuit where the devices begin to sporadically and/or periodically change operation, especially as the input voltage varies sinusoidally. In this specific radiation hardened shift register, the baseline circuit operation causes correct operation of dividing the input clock by 2× to create a 2.5 MHz (400 ns). As the radiation hardened shift register is irradiated and degrades, a new 1.667 MHz (600 ns) emission is gradually seen resulting from sporadic excursions beyond the part's newly degraded modified operating specification. These sporadic excursions caused by internal part noise and/or the 400 mV 200 Hz sinusoidal 3.4 V power variation causes components within the IC to occasionally operate improperly. Due to the design of the SNS54HC166-SP chip, the irradiation first causes incorrect operation as a result of one or more of its components resulting in a divide by 3 instead of a divide by 2 results using the circuit. These two correct and incorrect division operations are intermixed creating two frequencies which may be hard to view in the time domain output of FIG. 13. As degradation continues, occurrences of incorrect divide by 3 operation occurs more frequently until it exceeds the correct divide by 2 operation. This is observed as an increase in frequency peak dB heights of the 1.666 MHz artifact and a decrease in the 2.5 MHz artifact. As degradation continues, the 2.5 MHz peak indicating correct operation may disappear entirely and other components within the IC may begin to substantially degrade causing further incorrect operation and their associated frequency artifacts influenced by the circuit design may appear. With extreme irradiation, all circuits may not operate causing no frequency artifacts to appear.

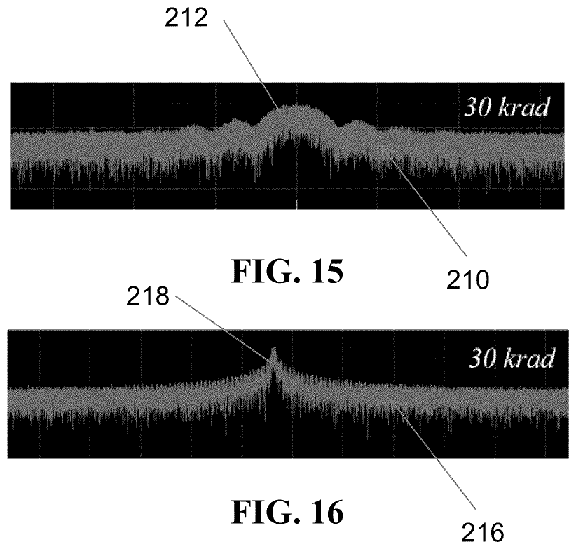

FIG. 15 illustrates an enlarged widened envelop 212 of a 2.5 MHz harmonic 210 after 30 krad radiation.

FIG. 16 illustrates an enlarged different envelop 218 of a 1.667 MHz harmonic 216 after 30 krad radiation.

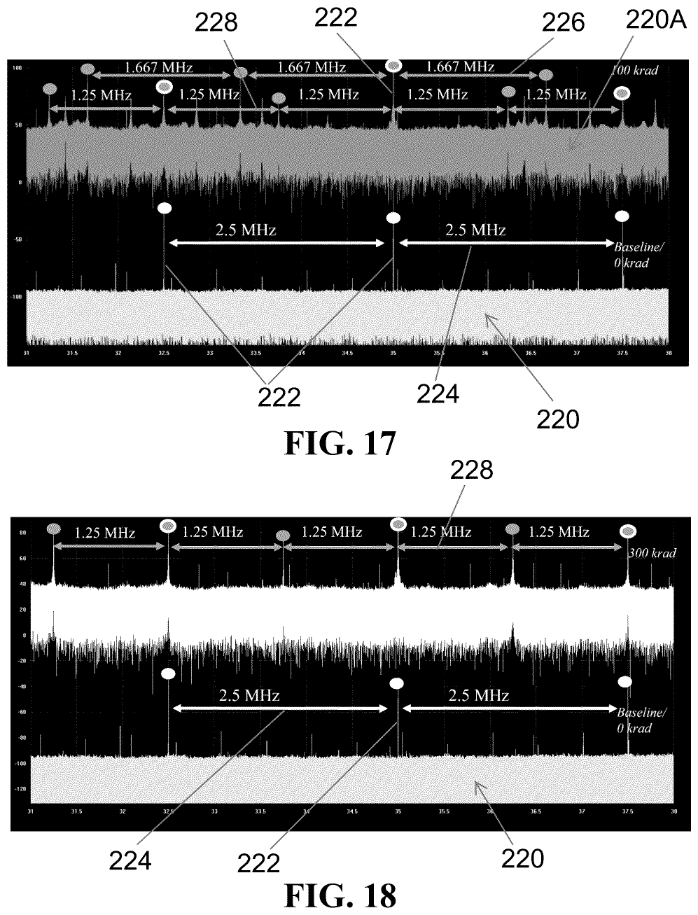

FIG. 17 illustrates a broadband view of a transition from the 2.5 MHz intended output frequency 224 (between the peaks 222) in a baseline emission signature 220 resulting from correct operation to a periodic, sporadic, or continuous incorrect operating state of a new unintended frequency 226 of 1.667 MHz and a further new unintended frequency 228 1.25 MHz at 100 krad of gamma irradiation, likely caused by incorrect operation of additional other components and observed in emission signature 220A. It can be seen that this further degradation and further frequency features may be causing sporadic, occasional, or continuous failure of more and more separate internal components in the electrical device. In this state, functional testing of all flip flop logics inside the electrical device may result in a 100% failure. In this state, functional testing of all flip flop logics inside the electrical device may result in an intermittent failure, as the output frequency shifts between a proper and improper working condition, progressing at a decreasing rate of correct operation, to a complete failure. For beta radiation type, this transition (toggling) to 1.667 MHZ output may also occur at 100 krad irradiation dose) and may stabilize at this frequency for 300 krad dose. In other words, the electrical device irradiated with 300 krad dose of beta type radiation may not degrade any further without substantially much more irradiation.

FIG. 18 illustrates a broadband view of a transition state for the gamma irradiated parts, with the 300 krad spectrum (top) having a 1.25 MHz output frequency 228 (800 ns duty cycle) in place of the intended 2.5 MHz output frequency 224. In other words, the electrical device exposed to 300 krad dose of gamma radiation may experience additional degradation. This increased degradation may manifest in an increase in the bit error rate. This increased degradation may manifest in an increase in a noise on communication signals that are being passed through the shift register. This increased degradation may manifest in a larger rate of events missed. Furthermore, an operation of the electronic component at the 1.25 MHz output frequency is two times slower than the designed output frequency of 2.5 MHz.

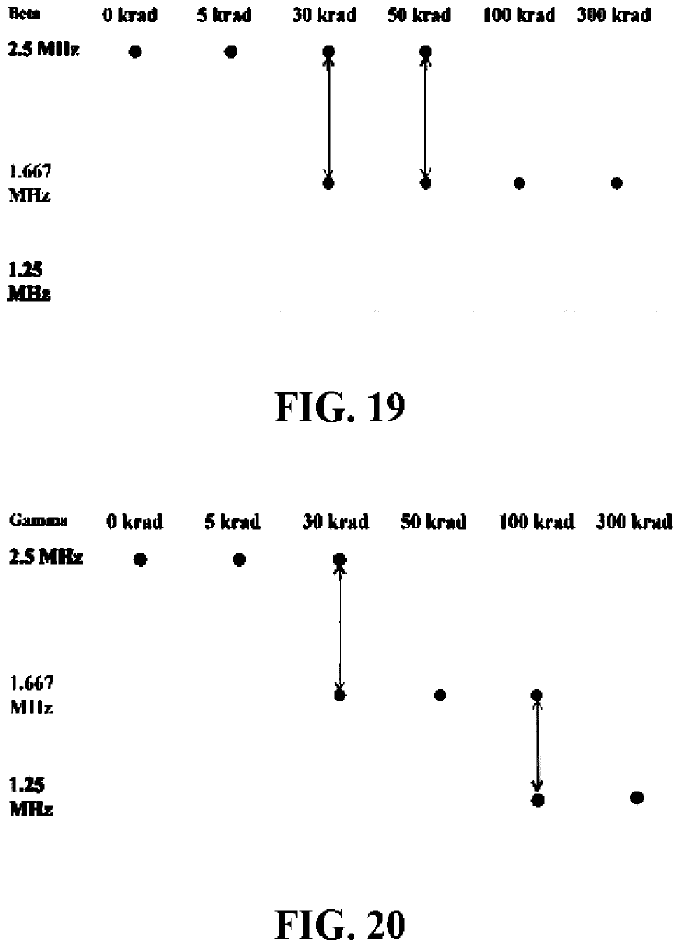

FIG. 19 illustrates effects on the shift register due to beta radiation. FIG. 19 illustrates also illustrates a threshold for functionality of the shift register (exposed to a beta radiation) that may be defined by a requirement that the shift register has a designed output operational frequency of 2.5 MHz. In a case of the beta irradiation at 30 krad and 50 krad, the ratio of intended output frequency to unintended output frequency may be ambiguous from just the data present in a broadband scan. Accordingly, a narrowband scan may be performed on a frequency region over a period of time to gain more acuity on a ratio of the correct and incorrect operation state of the 30 and 50 krad beta radiation.

In view of the above, the time domain voltage of output Q_{H} may provide a view into functionality of the shift register. When clock and power are first applied to the shift register (for the 30 krad beta dosed sample) the output is initially shifting between operational states (between 2.5 MHz and 1.667 MHz). The output may stabilize to the correct operational state of 2.5 MHz approximately 30 seconds after startup. At 50 krad of beta irradiation, the shift register may only be in a correct operational state for 10 seconds upon start up and then stabilize to the incorrect operational state resulting in the 1.6667 MHz output frequency with the 2.5 MHz output frequency disappearing.

The time domain voltage may be used to establish an operational or a functional threshold for a shift register. The above threshold states of the shift register may be used to improve a functional design of the shift register when used in circuit applications. Under this specific case, the exposure to 30 krad radiation dose may require an increased initial signal delay before input to the shift register can be used. In applications, where the shift register may be exposed to the 50 krad radiation dose, circuit design may be carried out to operate at a lower output frequency. Testing of the shift register exposed to radiation doses may also indicate applications where a specific shift register may not be used, unless redesigned. In an example, circuits used in satellite systems may experience radiation dose levels higher than 30 krad.

FIG. 20 illustrates effects on the shift register due to gamma radiation. It can be seen in FIG. 20 that gamma radiation may have a stronger effect on the shift register for the same krad dose than the beta radiation. However, both radiation types show a threshold degradation for functionality of the shift register at 30 krad. The broadband scan reveals that the 1.667 MHz harmonic feature is more prominent than the 1.25 MHz harmonic from the shape of the emitted peak in the frequency spectrum.

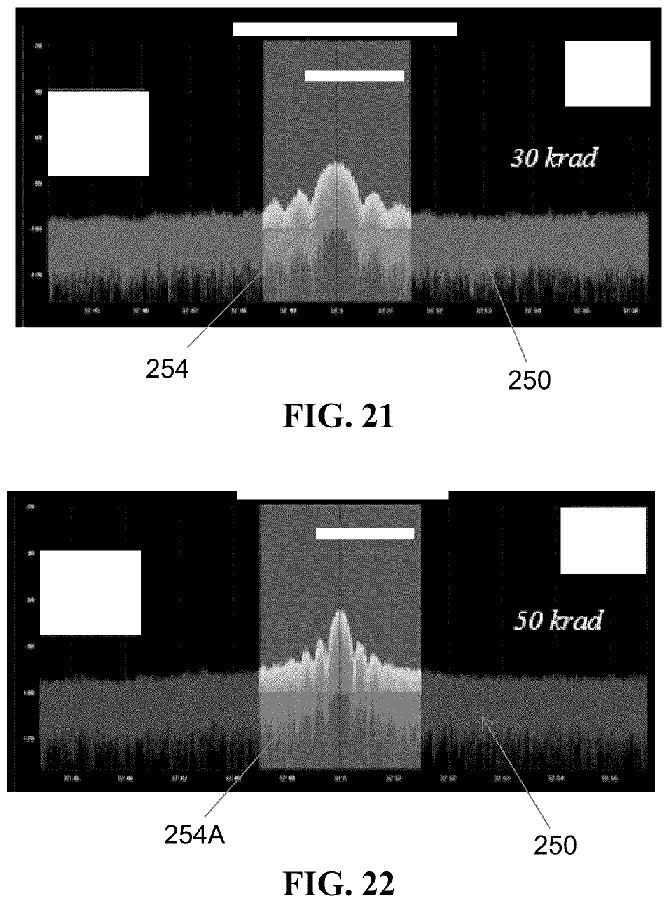

FIG. 21 illustrates an exemplary application of the narrowband analysis and particularly an application of a curve fit technique on a 2.5 MHz based harmonic frequency of 32.5 MHz from the shift register exposed to 30 krad dose. An area 254 of the emission signature 250 is being identified for analysis and radiation exposure derived RF frequency vs. amplitude artifacts.

FIG. 22 illustrates an exemplary application of the narrowband analysis and particularly an application of a curve fit technique on a 2.5 MHz based harmonic frequency of 32.5 MHz from the shift register exposed to a 50 krad dose. An area 254A of the emission signature 250 is being identified for analysis and radiation exposure derived RF frequency vs. amplitude artifacts.

FIGS. 21 and 22 illustrate how the curve fit technique may bring clarity into the situation as the analyzed peak is a harmonic of the 2.5 MHz clock and the metrics clearly illustrate that the presence of the 2.5 MHz harmonics are weaker in the 50 krad than in the 30 krad parts, as both the kurtosis and width at 10 dB down have both decreased by a significant percentage. In other words, the curve fit technique may improve analysis of a transition state caused by an increase from the 30 krad dose to the 50 krad dose.

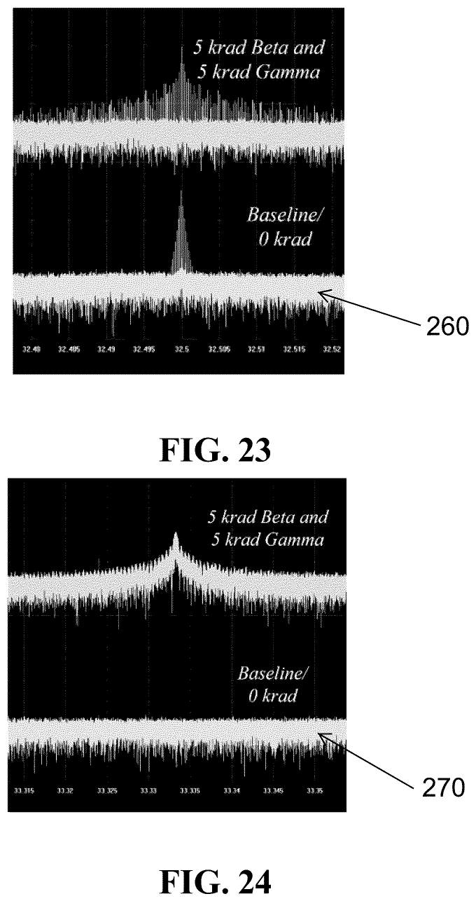

FIG. 23 illustrates a baseline signature 260 of the RF emission from the radiation hardened shift register 150 in a narrowband frequency domain and a corresponding signature after irradiation by a combination of a 5 krad of beta type radiation and a 5 krad of gamma type radiation, as is seen as a 2.5 MHz harmonic.

FIG. 24 illustrates a baseline signature 270 of the RF emission from the radiation hardened shift register 150 in a narrowband frequency domain and a corresponding signature after irradiation by a combination of a 5 krad of beta type radiation and a 5 krad of gamma type radiation, as is seen as a 1.667 MHz harmonic.

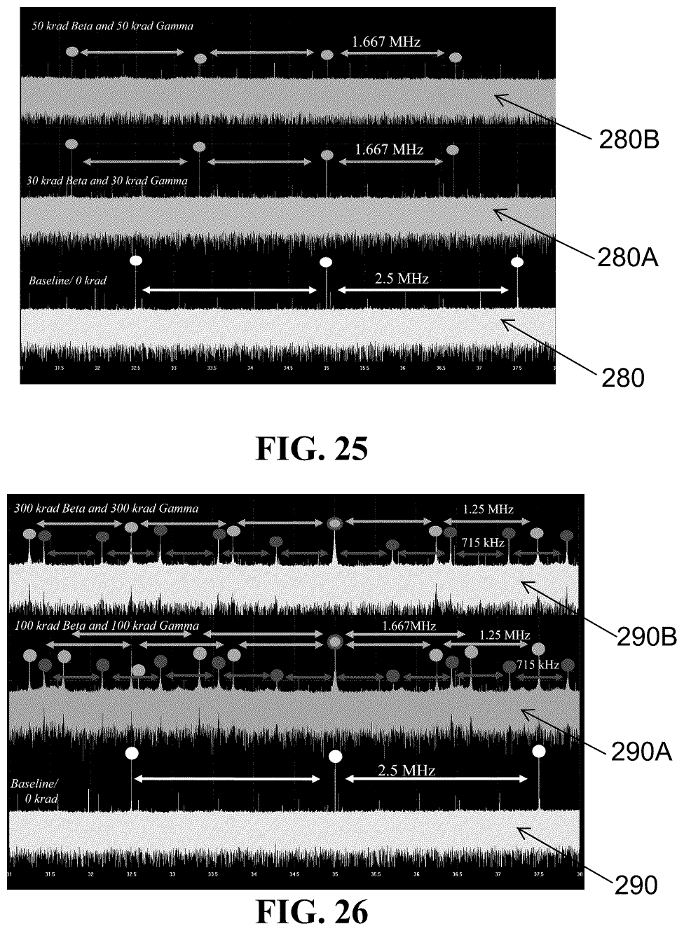

FIG. 25 illustrates a comparison of the baseline emission signature 280 to the 30+30 krad state emission signature 280A to the 50+50 krad state emission signature 280B.

FIG. 26 illustrates a comparison of the baseline emission signature 290 to the 100 Beta+100 Gamma krad state emission signature 290A to the 300 Beta+300 Gamma krad state emission signature 290B.

In view of the above, the sequential irradiation with beta and gamma consisted of six (6) doses where first the radiation hardened shift register was subject to beta radiation and then gamma radiation. Those levels are noted here as 5 krad beta and 5 krad gamma, 30 krad beta and 30 krad gamma, 50 krad beta and 50 krad gamma, 100 krad beta and 100 krad gamma, and 300 krad beta and 300 krad gamma.

There are similarities in the results of the sequential radiation, for example, the output frequency harmonics of 2.5 MHz degrades to 1.667 MHz, then to 1.25 MHz. FIG. 19 illustrates a start of an additional 4^{th} output frequency in the RF spectrum data (715 kHz) at the highest dosage level, 300 krad beta and 300 krad gamma.

Starting with the low dose effects at 5 krad beta and 5 krad gamma degradation is already present as the radiation hardened shift register is toggling between the 2.5 MHz harmonic frequency and the first degradation harmonic of 1.667 MHz, as shown in FIG. 16.

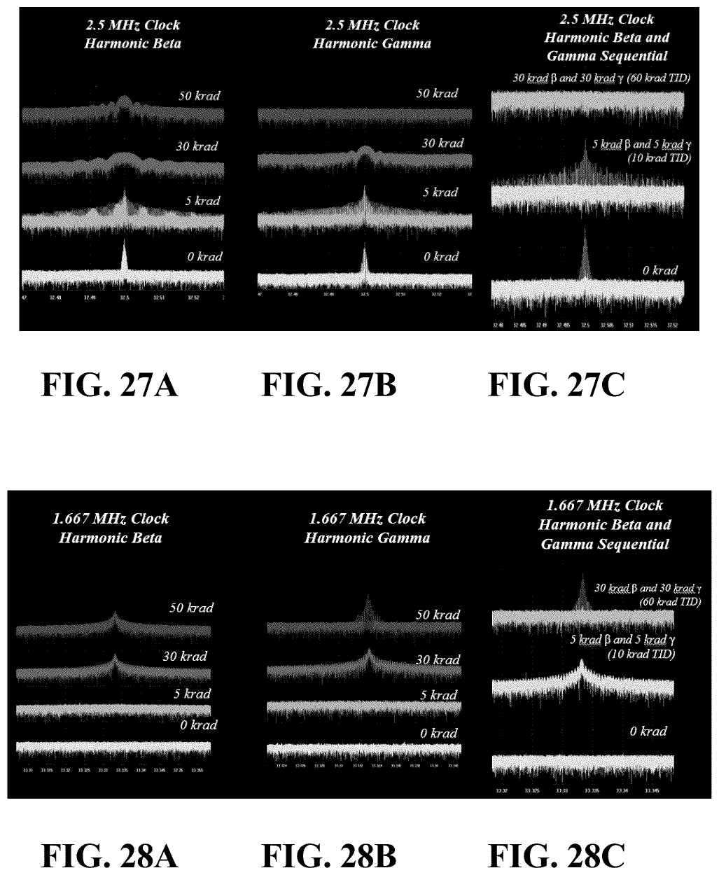

FIG. 27A illustrates a transition of RF signature of the 2.5 MHz harmonic at each iteration dose of a beta type radiation.

FIG. 27B illustrates a transition of RF signature of the 2.5 MHz harmonic at each iteration dose of a gamma type radiation.

FIG. 27C illustrates a transition of RF signature of the 2.5 MHz harmonic at each iteration dose of a beta and a gamma type sequential radiation.

FIG. 28A illustrates a transition of RF signature of the 1.667 MHz harmonic at each iteration dose of a beta type radiation.

FIG. 28B illustrates a transition of RF signature of the 1.667 MHz harmonic at each iteration dose of a gamma type radiation.

FIG. 28C illustrates a transition of RF signature of the 1.667 MHz harmonic at each iteration dose of a beta and a gamma type sequential radiation.

It can be seen from FIGS. 27A-28C that after 30 krad, the effects on the radiation hardened shift register diverge from beta effects and gamma effects in terms of severity of the effects. Increasing the dose rate to 50 krad in beta radiation, the radiation hardened shift register output will still emit unintended RF features with differences from 30 to 50 krad showing the movement of the new united harmonic frequency output (1.667 MHz) is starting to stabilize. When comparing the 30 and 50 krad doses, the RF spectrum shows that at 50 krad of gamma radiation the output has fully transitioned to the 1.667 MHz harmonic frequency output. At 50 krad of radiation is the first indicator that gamma radiation has a stronger effect on the electronics than beta radiation. This trend of gamma has a stronger effect on functionality of the radiation hardened shift register as the irradiation dose increases.

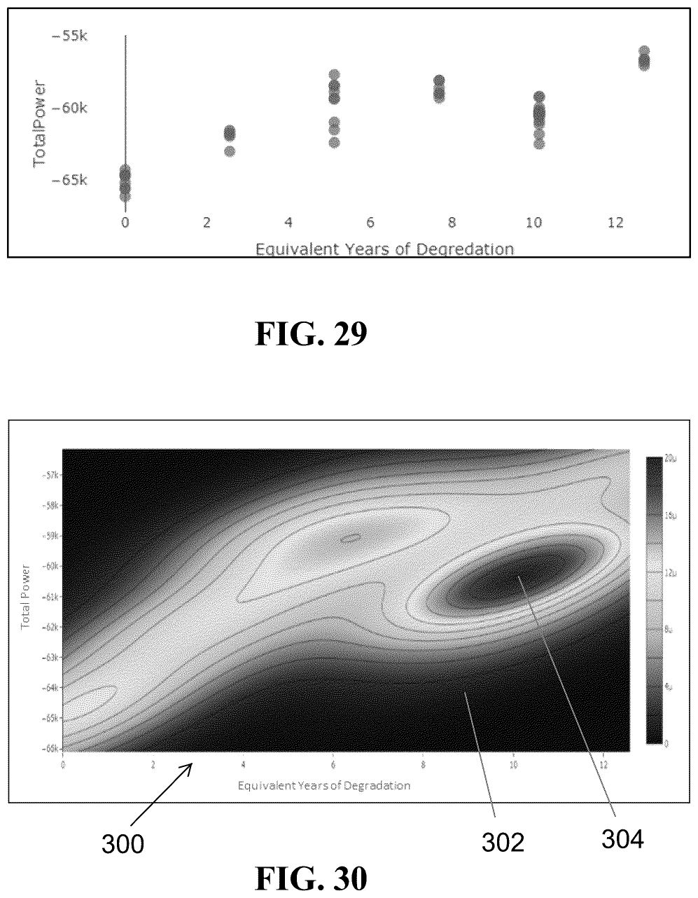

FIG. 29 illustrates an exemplary composite RF total emission power dB metric within a frequency region plotted as a function of krads of irradiation. The data is extracted from LN-200 device.

FIG. 30 illustrates an exemplary power density function (PDF) of a total irradiation within a frequency region as a heat map 300. In the heat map 300, a first area 302 being the lowest probability and a second area 304 being the highest probability of a device being irradiated at the approximate amount corresponding to a given total irradiation.

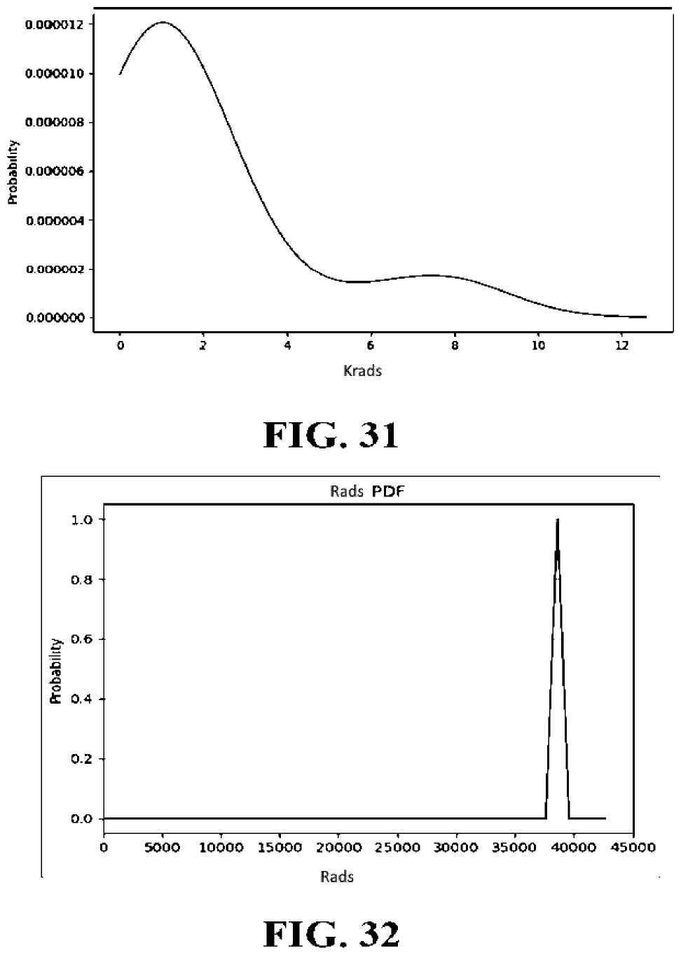

FIG. 31 illustrates a 2-D Probability Distribution for a Given metric measurement at the 900 rad power level. It can be seen a distribution of radiation exposure where there is the highest probability of measuring a 900 rad power level using the RF emission metrics detailed herein. There is a lower probability that other degradation amounts are true, as well. Simultaneous analysis of multiple metrics in the manner outlined may provide a significant increase in acuity of measurement.

FIG. 32 illustrates an exemplary probability distribution for an irradiation from measured data for the LN-200 device during a process wherein the device was artificially irradiated. The results show about 38,000 rads of exposure in the device.

### EMBODIMENTS

### Embodiment A

A method comprises steps of energizing, in a test fixture with a combination of a power signal and a clock signal, an electrical device selected from a plurality of electrical devices of a device; measuring a first value of a parameter of the electrical device in a first emission of an electromagnetic energy in a radio frequency (RF) spectrum emitted from energized electrical device; stressing the electrical device; measuring a second value of the parameter in the second emission of the electromagnetic energy in the RF spectrum emitted from the energized and stressed electrical device; measuring a difference between the first value and the second value; and determining a condition of the electrical device based on a measured difference.

A feature of this embodiment is that the stress comprises irradiating the electrical device with a radiation dose in a radiation type.

A feature of this embodiment is that the radiation type comprises a beta radiation.

A feature of this embodiment is that the radiation type comprises a gamma radiation.

A feature of this embodiment is that the radiation type comprises a combination of betta radiation and a gamma radiation.

A feature of this embodiment is that irradiating the electrical device comprises first irradiating the electrical device with a beta type radiation and then with a gamma type radiation.

A feature of this embodiment is that method further comprises incrementally increasing the radiation level; incrementally measuring a value of a parameter in an emission spectra at each increment of a radiation level increase; incrementally measuring a difference between the value of the parameter measured at each incremental emission spectra with a previous value; incrementally determining an operating response of the electrical device at each measured value of the parameter; and determining a value of the parameter at which the operating response of the electrical device is below a baseline.

A feature of this embodiment is that the condition comprises a level of functional degradation of the electrical device operating in a radiation type.

A feature of this embodiment is that the condition comprises a remaining useful life (RUL) of the electronic component.

A feature of this embodiment is that the condition comprises a degree of survivability of the electronic component operating in a radiation type.

A feature of this embodiment is that determining the condition comprises identifying an output of the electrical device.

A feature of this embodiment is that associating the condition comprises monitoring a state change of an output of the electrical device.

A feature of this embodiment is that the method further comprises modifying a design of the electrical device to withstand a higher level of irradiation.

A feature of this embodiment is that the method further comprises correlating the operating response to the value of the parameter.

A feature of this embodiment is that the stress comprises exposing the electrical device to an irradiation.

A feature of this embodiment is that the irradiation comprises exposing the electrical device to ions.

A feature of this embodiment is that the irradiation comprises exposing the electrical device to alpha particles.

A feature of this embodiment is that the irradiation comprises exposing the electrical device to beta particles.

A feature of this embodiment is that the irradiation comprises exposing the electrical device to gamma rays.

A feature of this embodiment is that the irradiation comprises exposing the electrical device to electromagnetic radiation with wavelengths below the visible spectrum.

### Embodiment B

A method comprises the steps of: energizing, in a test fixture with a combination of a power signal and a clock signal, an electrical device selected from a plurality of electrical devices of a device; measuring a first value of a parameter of the electrical device in a first emission of an electromagnetic energy in a radio frequency (RF) spectrum emitted from energized electrical device; irradiating the electrical device with a radiation dose in a radiation type; measuring a second value of the parameter in a second emission of the electromagnetic energy in the RF range emitted from the energized electrical device; measuring a difference between the second value and the first value; and associating a condition of the electrical device to a measured difference.

### Embodiment C

A method comprises: energizing an electrical device with a combination of a power signal and a clock signal; irradiating the electrical device with a series of radiation doses, each subsequent radiation dose being higher than a prior radiation dose; measuring a feature of the electrical device irradiated with each radiation dose; comparing the feature at the each radiation dose with the feature at the prior radiation dose; terminating irradiation when the feature at the subsequent radiation dose did not change from the feature at the prior radiation dose; and determining a functional performance of the electrical device at the radiation dose where the irradiation was terminated.

A feature of this embodiment is that energizing the electrical device comprises modulating the power signal.

A feature of this embodiment is that energizing the electrical device comprises energizing the electrical device with an oscillating clock signal.

A feature of this embodiment is that energizing the electrical device comprises energizing the electrical device with a combination of a power signal and an oscillating clock signal A feature of this embodiment is that measuring the feature of the electrical device comprises measuring an output frequency.

A feature of this embodiment is that irradiating the electrical device with the series of radiation levels comprises changing a radiation type.

A feature of this embodiment is that irradiating the electrical device with the series of radiation doses comprises irradiating the electrical device with one type of radiation at each dose within the series of radiation doses and then irradiating the electrical device with another type of radiation at the each level within the series of radiation doses.

A feature of this embodiment is that the method further comprises determining a functional status of the electrical device based on the functional performance.

### Embodiment D

A method of testing electrical devices for effects of radiation comprises steps of: a baseline collection and analysis of RF emissions from non-irradiated component; an assessment of baseline functional performance for non-irradiated component; a broadband collection and analysis of RF emissions for irradiated component for each planned dosage level; a narrowband collection and analysis of RF emissions for irradiated component for each planned dosage level; and an assessment of degradation to functional performance for irradiated component.

### Embodiment E

A method comprises the steps of: determining a baseline functional performance of the non-irradiated electrical device associated with a baseline signature of a collected emission of an electromagnetic energy in a radio frequency (RF) spectrum; determining a functional performance of an electrical device irradiated with a plurality of radiation doses based on a broadband collection and analysis of RF emissions; determining a functional performance of an electrical device irradiated with a plurality of radiation doses based on a narrowband collection and analysis of RF emissions; and assessing a degradation of the functional performance of irradiated electrical device at each radiation dose.

### Embodiment F

A method comprises: energizing an electrical device with a combination of a power signal and a clock signal; irradiating the electrical device with a radiation level; measuring a functional performance feature of the electrical device irradiated with the radiation level; irradiating the electrical device with a next radiation level; and measuring the functional performance feature of the electrical device irradiated with the next radiation level.

### Embodiment G

A method comprises: exposing an electrical device to an irradiation; analyzing a signature of an electromagnetic energy in a radio frequency (RF) spectrum emitted from the electrical device due to exposure to the irradiation stress; and determining a condition of the electrical device in a response to a result of an analyzed signature.

A feature of this embodiment is that analyzing the signature comprises energizing the electrical device and analyzing non-linear products from interactions within the electrical device.

A feature of this embodiment is that analyzing the signature comprises energizing the electrical device and determining a presence of an unintended amplitude modulation in the waveform.

A feature of this embodiment is that analyzing the signature comprises energizing the electrical device and determining a presence of an unintended frequency modulation in the waveform.

A feature of this embodiment is that analyzing the signature comprises energizing the electrical device and measuring changes in cross modulated frequencies.

A feature of this embodiment is that analyzing the signature comprises energizing the electrical device and determining a presence of evenly spaced peaks in the waveform.

A feature of this embodiment is that analyzing the signature comprises performing a harmonic analysis on the waveform.

A feature of this embodiment is that analyzing the signature comprises performing a non-harmonic analysis on the waveform.

A feature of this embodiment is that analyzing the signature comprises analyzing a plurality of emissions and determining a drift in the signature.

A feature of this embodiment is that determining the condition of the electrical device comprises assessing a performance degradation of the electrical device due to the irradiation.

### Embodiment H

A method comprises steps of: analyzing a parameter of an emission of an electromagnetic energy in a radio frequency (RF) spectrum from an electrical device being exposed to irradiation and energized with a combination of a power signal and a clock signal; and determining a condition of the electrical device in a response to analyzed parameter.

A feature of this embodiment is that the method further comprises exposing the electrical device to irradiation prior to analyzing the parameter.

A feature of this embodiment is that the method further comprises energizing the electrical device in a test fixture with a combination of a power signal and a clock signal prior to analyzing the parameter.

A feature of this embodiment is that the method further comprises using a rubidium clock to input the clock signal.

A feature of this embodiment is that analyzing the parameter comprises using a rubidium clock to reduce drifting of frequency bins.

A feature of this embodiment is that analyzing the parameter comprises using a receiver designed with a sensitivity of at least −146 dBm.

A feature of this embodiment is that analyzing the parameter comprises using a receiver designed with a sensitivity of about −170 dBm.

A feature of this embodiment is that analyzing the parameter comprises using a Low Noise Amplifier (LNA) with a noise factor of under 2.0.

A feature of this embodiment is that analyzing the parameter comprises lowering, with a Low Noise Amplifier (LNA), a noise floor of an emission signal.

A feature of this embodiment is that analyzing the parameter comprises using an analog to digital (AD) converter.

A feature of this embodiment is that analyzing the parameter comprises setting a resolution bandwidth at 0.1 seconds.

A feature of this embodiment is that analyzing the parameter comprises setting a resolution bandwidth at 1 second.

A feature of this embodiment is that analyzing the parameter comprises executing, with a signal processing unit, a curve fit algorithm.

A feature of this embodiment is that analyzing the parameter comprises measuring, with a signal processing unit, a peak amplitude at a center of a peak curve.

A feature of this embodiment is that analyzing the parameter comprises measuring, with a signal processing unit, a skewness of the peak curve in a relationship to an amplitude at a center of the peak curve.

A feature of this embodiment is that analyzing the parameter comprises measuring, with a signal processing unit, a spacing between peaks in the emission.

A feature of this embodiment is that analyzing the parameter comprises measuring, with a signal processing unit, a spacing between peaks in the emission and comparing measured spacing with a baseline spacing.

A feature of this embodiment is that analyzing the parameter comprises analyzing, with a spectrum analyzer in frequency domain, a shape of a peak curve in a digital waveform of an emission signal.

A feature of this embodiment is that analyzing the parameter comprises measuring, with a spectrum analyzer in frequency domain, an area under a peak curve in a digital waveform of an emission signal.

A feature of this embodiment is that measuring the area under the peak curve comprises measuring, with a spectrum analyzer in frequency domain, a shrinking of the curve over time.

A feature of this embodiment is that measuring the area under the peak curve comprises measuring, with a spectrum analyzer in frequency domain, a growth of the curve over time.

A feature of this embodiment is that analyzing the parameter comprises identifying, with a spectrum analyzer in frequency domain, a series of evenly spaced peaks in a digital waveform of an emission signal.

A feature of this embodiment is that analyzing the parameter comprises measuring, with a spectrum analyzer in frequency domain, a sharpness of a peak curve in a digital waveform of an emission signal.

A feature of this embodiment is that analyzing the parameter comprises performing, with a signal processing unit, a harmonic analysis.

A feature of this embodiment is that analyzing the parameter comprises performing, with a signal processing unit, a non-harmonic analysis.

A feature of this embodiment is that analyzing the parameter comprises performing, with a signal processing unit, a drift of any two adjacent peaks in a digital waveform of an emission signal.

A feature of this embodiment is that analyzing the parameter comprises determining, with a signal processing unit, a drift of a peak in a digital waveform of an emission signal over time.

A feature of this embodiment is that analyzing the parameter comprises comparing, with a signal processing unit, a location of a peak with a baseline peak location and measuring, with the signal processing unit, a peak drift.

A feature of this embodiment is that analyzing the parameter comprises combining emission signals from two adjacent traces of the electrical device in a time domain resulting in nonlinear distortion and intermodulation products in them and measuring a resulting frequency artifact of the emission.

A feature of this embodiment is that analyzing the parameter comprises combining emission signals from two adjacent traces of the electrical device in a time domain resulting in nonlinear distortion and intermodulation products in them and measuring a resulting amplitude artifact of the emission.

A feature of this embodiment is that determining the condition comprises determining a remaining useful life (RUL).

A feature of this embodiment is that determining RUL comprises using a kernel estimator.

A feature of this embodiment is that determining RUL comprises using a Bayes' theorem.

A feature of this embodiment is that determining the condition comprises generating a probability density function (PDF) to determine irradiation of the electrical device.

A feature of this embodiment is that analyzing the parameter comprises identifying a difference between the parameter and a baseline parameter.

A feature of this embodiment is that analyzing the parameter comprises shielding the electrical device from external noise.

A feature of this embodiment is that analyzing the parameter comprises: measuring a first value of the parameter in the emission from energized and unirradiated electrical device; measuring a second value of the parameter in the emission from the energized and irradiated electrical device; and measuring a difference between the first value and the second value.

### Embodiment I

A method comprises: exposing an electrical device to an irradiation by at least one of alpha radiation, a beta radiation and a gamma radiation; analyzing a signature of a waveform of an electromagnetic energy in a radio frequency (RF) spectrum emitted from the electrical device due to exposure to irradiation; and determining a condition of the electrical device in a response to a result of an analyzed signature.

### Embodiment J

A method comprises steps of: analyzing a parameter of an emission of an electromagnetic energy in a radio frequency (RF) range from an electrical device being exposed to an irradiation stress and energized with a combination of a power signal and a clock signal; identifying a difference between the parameter and a baseline parameter; and associating a irradiation condition of the electrical device in a response to identified difference.

### Embodiment K

A non-transitory machine-readable medium, the machine-readable storage medium including instructions that when executed by one or more processors of a machine, cause the machine to perform operations comprising: analyzing a signature of an unintended emission of an electromagnetic energy in a radio frequency (RF) spectrum; comparing the signature against a baseline signature; and identifying a irradiation condition of an electrical device based on a comparison.

### Embodiment L

A non-transitory machine-readable medium, the machine-readable storage medium including instructions that when executed by one or more processors of a machine, cause the machine to perform operations comprising: analyzing, with a curve fit algorithm, a signature of an unintended emission of an electromagnetic energy in a radio frequency (RF) spectrum; comparing the signature against a baseline signature and identifying a irradiation condition of an electrical device based on a comparison.

Features which are described in the context of separate embodiments may also be provided in combination in a single embodiment. Conversely, various features which are, for brevity, described in the context of a single embodiment, may also be provided separately or in any suitable subcombination. Each embodiment may be employed alone or in any combination, and may include any one or more of the above features in any suitable combination. The Applicant hereby gives notice that new Claims may be formulated to such embodiments and features and/or combinations of such embodiments and features during the prosecution of the present Application or of any further Application derived therefrom.

The chosen embodiments of the subject matter have been described and illustrated, to plan and/or cross section illustrations that are schematic illustrations of idealized embodiments, for practical purposes so as to enable any person skilled in the art to which it pertains to make and use the same. As such, variations from the shapes of the illustrations as a result, for example, of manufacturing techniques and/or tolerances, are to be expected. It is therefore intended that all matters in the foregoing description and shown in the accompanying drawings be interpreted as illustrative and not in a limiting sense. For example, a region illustrated or described as flat may, typically, have rough and/or nonlinear features. Moreover, sharp angles that are illustrated may be rounded and rounded angles may be sharp. Thus, the regions illustrated in the figures are schematic in nature and their shapes are not intended to illustrate the precise shape of a region and are not intended to limit the scope of the present claims. It will be understood that variations, modifications, equivalents and substitutions for components of the specifically described embodiments may be made by those skilled in the art without departing from the spirit and scope of the invention as set forth in the appended claims.

Unless otherwise indicated, all numbers expressing quantities of elements, optical characteristic properties, and so forth used in the specification and claims are to be understood as being modified in all instances by the term “about.” The term “about” may be associated with a numerical value to indicate a margin of +/−20% of the value. Accordingly, unless indicated to the contrary, the numerical parameters set forth in the preceding specification and attached claims are approximations that can vary depending upon the desired properties sought to be obtained by those skilled in the art utilizing the teachings of the present subject matter. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the claimed subject matter are approximations, the numerical values set forth in the specific examples are reported as precisely as possible.

Any numerical value, however, inherently contains certain errors necessarily resulting from the standard deviations found in their respective testing measurements.

To the extent that the appended claims have been drafted without multiple dependencies, this has been done only to accommodate formal requirements in jurisdictions which do not allow such multiple dependencies or require extra claim fees for such multiple dependencies. It should be noted that all possible combinations of features which would be implied by rendering the claims multiply dependent are explicitly envisaged and should be considered part of the invention.

Anywhere the term “comprising” is used, embodiments and components “consisting essentially of” and “consisting of” are expressly disclosed and described herein.”

Any element in a claim that does not explicitly state “means for” performing a specified function, or “step for” performing a specified function, is not to be interpreted as a “means” or “step” clause as specified in 35 U.S.C. § 112, ¶6. In particular, any use of “step of” in the claims is not intended to invoke the provision of 35 U.S.C. § 112, ¶6.

The Abstract is not intended to be limiting as to the scope of the claimed subject matter and is for the purpose of quickly determining the nature of the claimed subject matter.

What is claimed is:

1. A method, comprising steps of:
energizing, in a test fixture with a combination of a power signal and a clock signal, an electrical device selected from a plurality of electrical devices of a device;
measuring a first value of a parameter of the electrical device in a first emission of an electromagnetic energy in a radio frequency (RF) spectrum emitted from energized electrical device;
irradiating the electrical device with a radiation dose in a radiation type;
measuring a second value of the parameter in a second emission of the electromagnetic energy in the RF spectrum emitted from energized and irradiated electrical device;
measuring a difference between the first value and the second value; and
determining a condition of the electrical device based on a measured difference.

2. The method of claim 1, further comprising:
incrementally increasing the radiation dose;
incrementally measuring a value of a parameter in an emission spectra at each increment of a radiation dose increase;
incrementally measuring a difference between the value of the parameter measured at each incremental emission spectra with a previous value;
incrementally determining an operating response of the electrical device at each measured value of the parameter; and
determining a value of the parameter at which the operating response of the electrical device is below a baseline.

3. A method, comprising steps of:
exposing an electrical device to an irradiation;
analyzing a signature of an electromagnetic energy in a radio frequency (RF) spectrum emitted from the electrical device due to exposure to the irradiation; and
determining a condition of the electrical device in a response to a result of an analyzed signature.

4. The method of claim 3, wherein analyzing the signature comprises energizing the electrical device and analyzing non-linear products arising from operation of the electrical device.

5. The method of claim 3, wherein analyzing the signature comprises energizing the electrical device and determining a presence of an unintended amplitude modulation in a waveform.

6. The method of claim 3, wherein analyzing the signature comprises energizing the electrical device and determining a presence of an unintended frequency modulation in a waveform.

7. The method of claim 3, wherein analyzing the signature comprises energizing the electrical device and measuring changes in cross modulated frequencies.

8. The method of claim 3, wherein analyzing the signature comprises energizing the electrical device and determining a presence of evenly spaced peaks in a waveform.

9. The method of claim 3, wherein analyzing the signature comprises performing a harmonic analysis on a waveform.

10. The method of claim 3, wherein analyzing the signature comprises performing a non-harmonic analysis on a waveform.

11. The method of claim 3, wherein analyzing the signature comprises analyzing a plurality of emissions and determining a drift in the signature.

12. The method of claim 3, wherein determining the condition of the electrical device comprises estimating remaining useful life (RUL) of the electrical device using an equation of:
$$P ( {RUL}_{i} \vert \{ S \} ) = \frac{{\prod }_{j = 1}^{m} P ( {S}_{j} \vert {RUL}_{i} )}{{\sum }_{i = i}^{n} 〈 {\prod }_{j = 1}^{m} P ( {S}_{j} \vert {RUL}_{j} ) 〉}$$
where:
P—probability
RULᵢ—particular RUL value
{S}—measured set of emission signature parameters
I—indices
j—indices
n—number of discrete RUL values considered
m—number of properties in a property set.

13. A method, comprising steps of:
analyzing a parameter of an emission of an electromagnetic energy in a radio frequency (RF) spectrum from an electrical device being exposed to an irradiation and energized with a combination of a power signal and a clock signal; and
determining a condition of the electrical device in a response to analyzed parameter.

14. The method of claim 13, further comprising energizing the electrical device in a test fixture with a combination of a power signal and a clock signal prior to analyzing the parameter.

15. The method of claim 13, wherein analyzing the parameter comprises using a receiver designed with a sensitivity of about −170 dBm.

16. The method of claim 13, wherein analyzing the parameter comprises using a Low Noise Amplifier (LNA) with a noise figure of under 2 dB.

17. The method of claim 13, wherein analyzing the parameter comprises setting a resolution bandwidth of at least 0.1 Hz.

18. The method of claim 13, wherein analyzing the parameter comprises executing, with a signal processing unit, a curve fit algorithm.

19. The method of claim 13, wherein determining the condition comprises determining a remaining useful life (RUL) under extrapolated irradiation levels.

20. The method of claim 19, wherein determining RUL comprises using a kernel estimator.

21. The method of claim 19, wherein determining RUL comprises using a Bayes' theorem.

22. The method of claim 13, wherein determining the condition comprises generating a probability density function (PDF).
